(19) United States
(12) Patent Application Publication
(10) Pub. No.: US 2025/0212486 A1
(43) Pub. Date: Jun. 26, 2025

(54) CONVERTER AND METHOD FOR FORMING THE SAME

(71) Applicants: TAIWAN SEMICONDUCTOR MANUFACTURING COMPANY, LTD., Hsinchu (TW); TSMC CHINA COMPANY LIMITED, Shanghai (CN)

(72) Inventors: LinChun GUI, Shanghai City (CN); Cheng Lin ZHANG, Shanghai City (CN); ShengTian LU, Shanghai City (CN); Jian-Hua LU, Shanghai City (CN); Lianjie LI, Shanghai City (CN)

(73) Assignees: TAIWAN SEMICONDUCTOR MANUFACTURING COMPANY, LTD., Hsinchu (TW); TSMC CHINA COMPANY LIMITED, Shanghai (CN)

(21) Appl. No.: 18/405,890

(22) Filed: Jan. 5, 2024

(30) Foreign Application Priority Data
Dec. 26, 2023 (CN) 202323591474.1

(51) Int. Cl. H01L 29/423; H01L 29/40; H01L 29/78

(52) U.S. Cl. CPC H10D 64/516; H10D 1/20; H10D 30/65; H10D 64/01

(57) ABSTRACT

A converter includes a substrate, a first transistor, a second transistor, a first gate contact plug, a first source contact plug, a first metal line, and an inductor. The first transistor includes a first gate structure, a first source region, and a first drain region. The second transistor includes a second gate structure, a second source region, and a second drain region. The first gate contact plug is electrically connected to the first gate structure. The first source contact plug is electrically connected to the first source region. The first metal line is in contact with a top surface of the first gate contact plug and a top surface of the first source contact plug. The inductor is electrically connected to the first drain region of the first transistor and the second source region of the second transistor.

### PRIORITY CLAIM AND CROSS-REFERENCE

The present application claims priority to China Application Serial Number 202323591474.1, filed Dec. 26, 2023, which is herein incorporated by reference.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a circuit diagram of a converter in accordance with some embodiments of the present disclosure.

FIGS. 2A and 2B illustrate different operation modes of a converter in accordance with some embodiments of the present disclosure.

FIG. 3A illustrates a top view of a converter in accordance with some embodiments of the present disclosure.

FIGS. 3B to 3E illustrate cross-sectional views of a converter in accordance with some embodiments of the present disclosure.

FIG. 4 illustrates a top view of a converter in accordance with some embodiments of the present disclosure.

FIGS. 5A to 18E are schematic views of a converter in various stages of fabrication in accordance with some embodiments of the present disclosure.

FIGS. 19A and 19B illustrate cross-sectional views of a converter in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

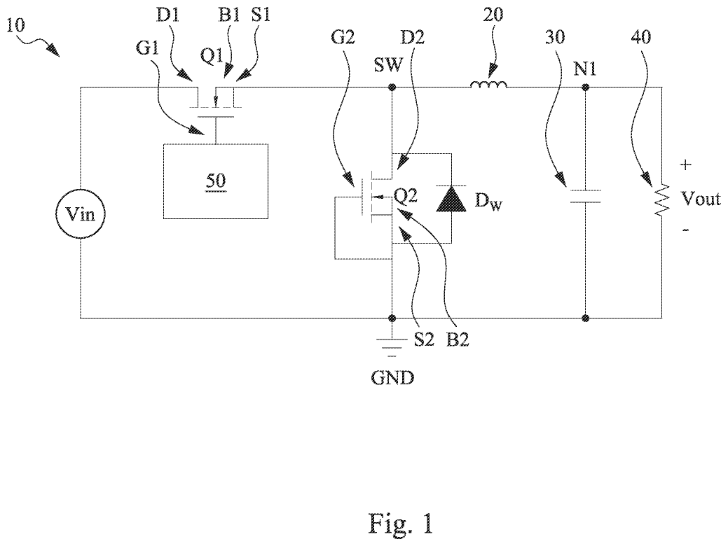

FIG. 1 is a circuit diagram of a converter in accordance with some embodiments of the present disclosure. Shown there is an exemplary circuit diagram of a converter 10. In some embodiments, the converter 10 is a synchronous buck converter. The synchronous buck converter 10 includes a network of active and passive components coupled between an input terminal and an output terminal. The input terminal receives the regulated voltage Vin, and the modulated voltage is produced at the output terminal as Vout.

The synchronous buck converter 10 illustrated in FIG. 1 includes a high-side (HS) transistor Q1 and a low-side (LS) transistor Q2. In some embodiments, the high-side transistor Q1 and the low-side transistor Q2 may be field-effect-transistor (FET), and thus the high-side transistor Q1 and the low-side transistor Q2 can also be referred to as high-side field-effect-transistor (HS FET) Q1 and low-side field-effect-transistor (LS FET) Q2, respectively.

The HS transistor Q1 and the LS transistor Q2 are connected in series and across a supply voltage terminal Vin and ground GND. In greater details, the drain region D1 of the HS transistor Q1 is electrically connected to the supply voltage terminal Vin. The source S1 and the body B1 of the HS transistor Q1 is electrically connected to a node SW. Moreover, the drain D2 of the LS transistor Q2 is electrically connected to the node SW. That is, the source S1 and the body B1 of the HS transistor Q1 are electrically connected to the drain D2 of the LS transistor Q2. The source S2 and the body B2 of the LS transistor Q2 are electrically connected to the ground GND. In some embodiments, the gate G1 of the HS transistor Q1 is electrically connected a driver 50. In some embodiments, the driver 50 is configured to supply (or stop supplying) a relative high voltage level to turn on (or turn off) the HS transistor Q1. On the other hand, the gate G2 of the LS transistor Q2 is electrically connected to the source S2 and the body B2 of the LS transistor Q2.

The synchronous buck converter 10 further includes an inductor 20, a capacitor 30, and a resistor 40. In some embodiments, a first side of the inductor 20 is electrically connected to the node SW. That is, the first side of the inductor 20 is electrically connected to the source S1 and the body B1 of the HS transistor Q1 and the drain D2 of the LS transistor Q2. A second side of the inductor 20 is electrically connected to a node N1. Moreover, a first side of the capacitor 30 is electrically connected to the node N1, and a second side of the capacitor 30 is electrically connected to the ground GND. Similarly, a first side of the resistor 40 is electrically connected to the node N1, and a second side of the resistor 40 is electrically connected to the ground GND. In some embodiments, the node N1 can also be referred to as output voltage terminal. In some embodiments, the resistor 40 may simulate a load. The load is attributable to device connected to the synchronous buck converter 10, the device being, for example, a commutation device. The combination of inductor 20 and the capacitor 30 may ensure the current through the load resistor 40 and voltage across the load resistor 40 may not change instantaneously.

In some embodiments, the LS transistor Q2 may work in synchrony with the HS transistor Q1 to controllably switch the inductive network of the synchronous buck converter 10. For example, the driver 50 is configured to supply a control signal to the gate G1 of the HS transistor Q1, so as to periodically turn on and off the HS transistor Q1.

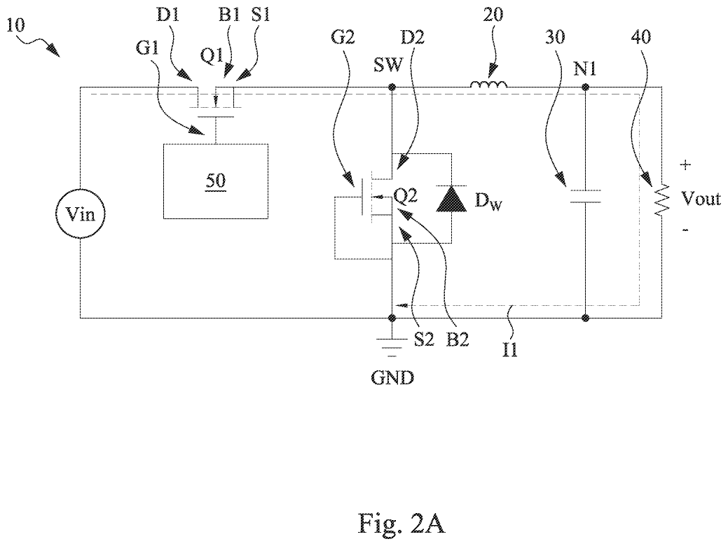

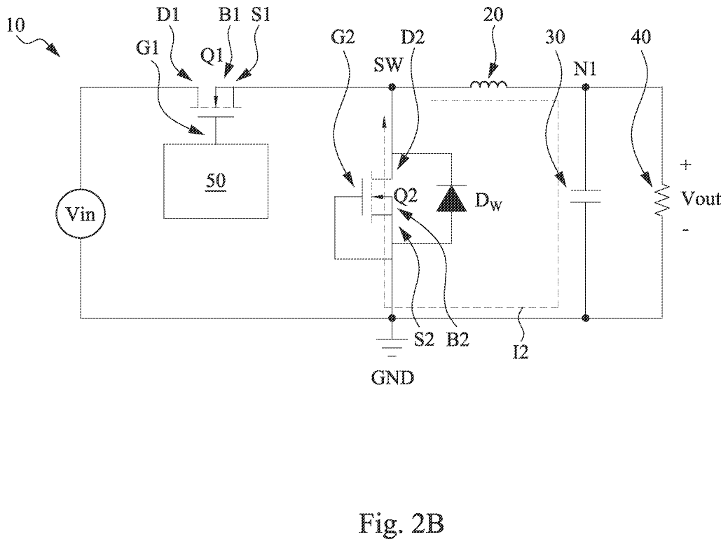

FIGS. 2A and 2B illustrate different operation modes of a converter in accordance with some embodiments of the present disclosure. As shown in FIG. 2A, in a first operation mode of the converter 10, the HS transistor Q1 is turn ON, the supply voltage level Vin will be transferred over the HS transistor Q1 to node SW. For example, the driver 50 may supply a high voltage level to the gate G1 of the HS transistor Q1 to turn on the HS transistor Q1. Accordingly, the node SW is at a high voltage level. Meanwhile, the gate G2 and the source S2 of the LS transistor Q2 are equipotential 0V, and will be automatically turn OFF. In the first operation mode, current path I1 flows from the supply voltage terminal Vin in a forward direction through the HS transistor Q1 to the node SW. The current is blocked by the LS transistor Q2 and flows through the inductor 20 as shown by the current path I1.

When the converter 10 is operated in the first operation mode, if the gate-source voltage of the HS transistor Q1 is switched to low or OFF (e.g., to V_{GS}<V_{TH}), such that the gate G1 of the HS transistor Q1 is biased OFF, the converter 10 is therefore switched to a second operation mode as shown in FIG. 2B.

As shown in FIG. 2B, in a second operation mode of the converter 10, when the HS transistor Q1 is turn OFF, the Vin is cut off and the current is also dramatically off at the node SW. However, due to the characteristic of the inductor 20, the inductance current of the inductor 20 cannot be abrupt drop, so the current path will go through the LS transistor Q2 to keep the inductance current, as shown by the current path 12. Accordingly, the voltage at the node SW may be reduced to a lower level (e.g., −0.7 V in some embodiments). In such condition, the LS transistor Q2 will be turn on because source and drain of the LS transistor Q2 has been reversely put (physical source acted as electrical drain and physical drain acted as electrical source), so the LS transistor Q2 will be turned on to conduct the wheeling current from inductance. Under the second operation mode, the LS transistor Q2 can be equivalently referred to as a wheeling diode D_{W}. In greater details, because the gate G2 and the source S2 of the LS transistor Q2 are short, the LS transistor Q2 can be automatically turn ON without using an external driver to supply a turn on voltage to the gate G2 of the LS transistor Q2.

In some embodiments of the present disclosure, electrically connecting the gate G2 of the LS transistor Q2 to the source S2 of the LS transistor Q2 may be beneficial for lowering power consumption. For example, because the gate G2 and the source S2 of the LS transistor Q2 are short, the LS transistor Q2 can be automatically turn ON without using an external driver to supply a turn on voltage to the gate G2 of the LS transistor Q2. In some embodiments where the gate G2 and the source S2 of the LS transistor Q2 are not electrically connected to each other, an extra driver may be designed for electrically switch the LS transistor Q2 instead of passive diode automatically switch, and thus driver loss issue may occur.

Moreover, in the embodiments where the gate G2 and the source S2 of the LS transistor Q2 are not electrically connected to each other, the HS transistor Q1 and the LS transistor Q2 should be avoided simultaneously at “ON” state, otherwise the circuit will be short directly from Vin to ground GND and the device might be catastrophically destroyed. In such condition, “dead time” needs to be put during the HS transistor Q1 and the LS transistor Q2 internally switching “ON” and “OFF”. For example, a time delay is between the turn-off of the HS transistor Q1 and the turn-on of the LS transistor Q2. However, during the “dead time”, the LS transistor Q2 has not been turn on (e.g., in the OFF state), the current may still pass through parasitic body diode, which will induce diode reverse recovery loss (Qrr). As the switching frequency reaches to MHz, the Qrr loss is rising up to be one of the major issue of power loss following by switching loss, which is around 20˜30% of total loss.

The provided converter 10 of the embodiments of the present disclosure will be beneficial for high-power high-frequency buck converter module in data-center application with load current >20 A and switch frequency >1-2 MHz compared to conventional discrete solution with 500 KHz, the higher current the bigger parasitic Vsub=I*Rsub and will be easier to automatically turn on the LS transistor and bring less Qrr in dead time and finally obtain a higher efficiency (˜90% at 2 MHz).

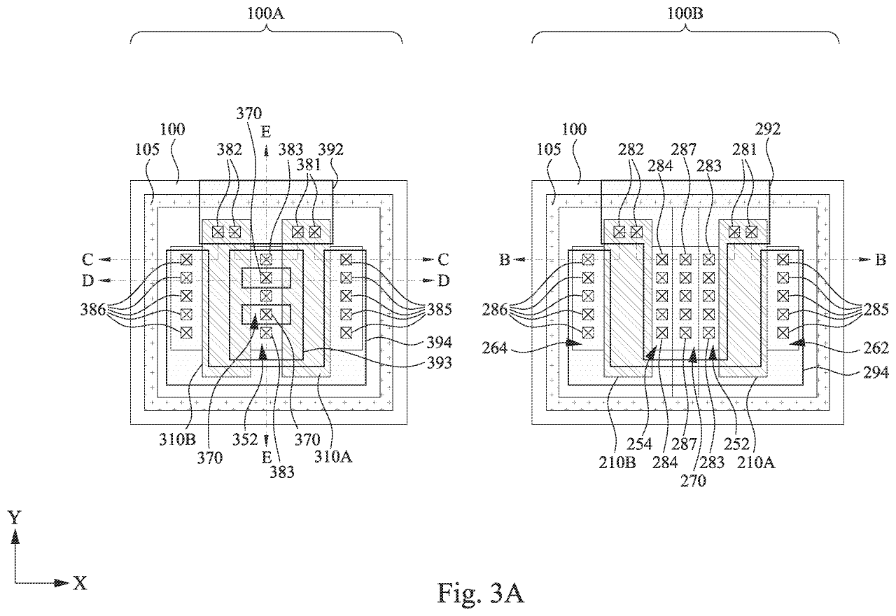

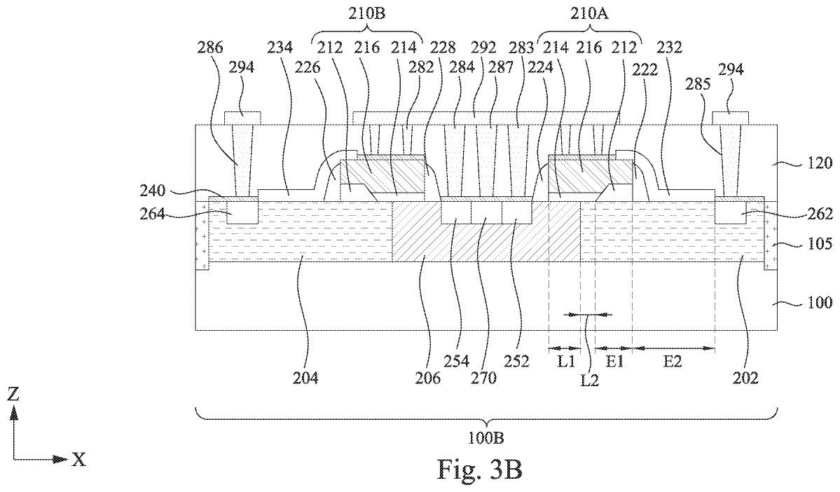

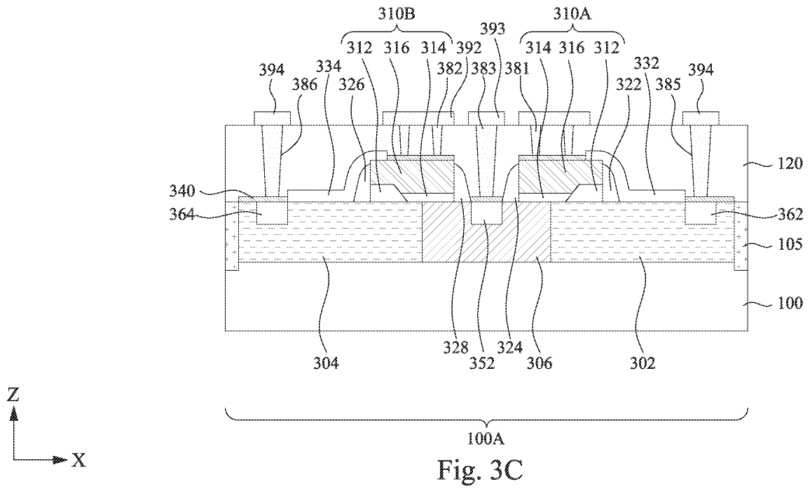

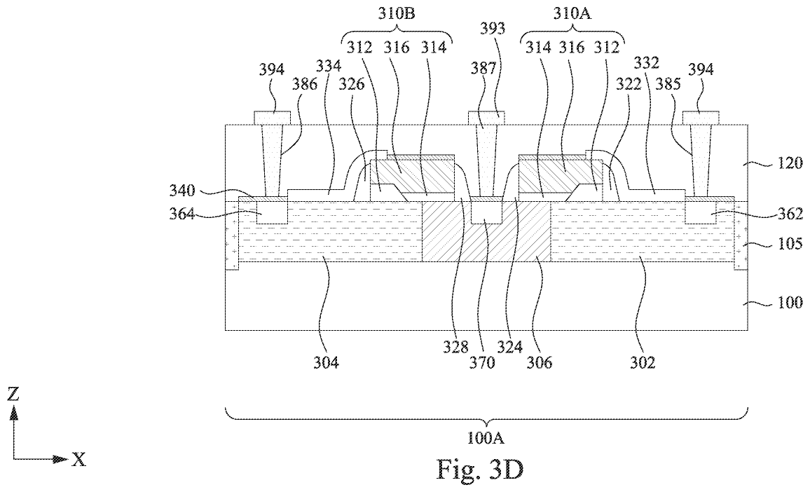

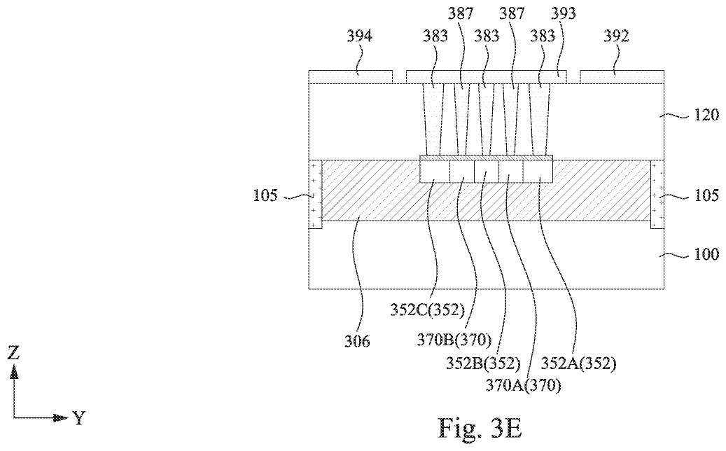

FIG. 3A illustrates a top view of a converter in accordance with some embodiments of the present disclosure. FIGS. 3B to 3E illustrate cross-sectional views of a converter in accordance with some embodiments of the present disclosure. In greater details, FIG. 3B is a cross-sectional view along line B-B of FIG. 3A, FIG. 3C is a cross-sectional view along line C-C of FIG. 3A, FIG. 3D is a cross-sectional view along line D-D of FIG. 3A, and FIG. 3E is a cross-sectional view along line E-E of FIG. 3A. It is noted that some elements described in the cross-sectional views of FIGS. 3B to 3E are not illustrated in the top view of FIG. 3A for brevity. FIGS. 3A to 3E may illustrate an exemplary semiconductor structure of the converter 10 as discussed in FIGS. 1 to 2B, and thus some elements are labeled the same and relevant details will not be repeated.

Shown there is a substrate 100. In some embodiments, the substrate 100 may function to provide mechanical and/or structure support for features or structures. These features or structures may be parts or portions of an integrated circuit (e.g. the converter 10) that may be formed on or over the substrate 100.

The substrate 100 may include a first region 100A and a second region 100B. In some embodiments, the first region 100A of the substrate 100 can be referred to the region where a high-side (HS) transistor Q1 is formed, and the second region 100B of the substrate 100 can be referred to the region where a low-side (LS) transistor Q2 is formed. In greater details, the cross-sectional view of FIG. 3B illustrates a cross-sectional view of the LS transistor Q2, and the cross-sectional views of FIGS. 3C to 3E illustrate cross-sectional views of the HS transistor Q1.

Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates. In some other embodiments, the substrate 100 may include sapphire (e.g. crystalline Al₂O₃), e.g. a large grain or a single crystalline layer of sapphire or a coating of sapphire. As another example, the substrate 100 may be a sapphire substrate, e.g. a transparent sapphire substrate comprising, as an example, α-Al₂O₃. Other elementary semiconductors like germanium may also be used for substrate 100.

In some embodiments, the substrate 100 may be a p-type substrate. For example, the substrate 100 may be doped with p-type dopants. Examples of p-type dopants can be B, Al, Ga, In, or the like.

Isolation structures 105 are disposed in the substrate 100. The isolation structures 105 can be referred to as shallow trench isolation (STI) structures. In some embodiments, the isolation structures 105 are made of silicon oxide, silicon nitride, silicon oxynitride, fluoride-doped silicate glass (FSG), or other low-K dielectric materials. In some embodiments, the isolation structures 105 can have a multi-layer structure, for example, a thermal oxide liner layer with silicon nitride over the liner.

As shown in the top view of FIG. 3A, one isolation structure 105 is in the substrate 100 and surrounds the first region 100A of the substrate 100, so as to electrically isolate the electrical components formed over the first region 100A of the substrate 100 from other components outside the first region 100A of the substrate 100. Similarly, another one isolation structure 105 is in the substrate 100 and surrounds the second region 100B of the substrate 100, so as to electrically isolate the electrical components formed over the second region 100B of the substrate 100 from other components outside the second region 100B of the substrate 100. In some embodiments, each of the isolation structure 105 may include a rectangular ring-shape top profile.

Reference is made to FIGS. 3A and 3B. The second region 100B of the substrate 100 may include a drift region 202, a drift region 204, and a body region 206 between the drift region 202 and the drift region 204. In some embodiments, the drift regions 202 and 204 may be doped with n-type dopants, and can also be referred to as n-type drift regions 202 and 204. On the other hand, the body region 206 may be doped with p-type dopants, and can also be referred to as p-type body region 206. Examples of p-type dopants can be B, Al, Ga, In, or the like. Examples of n-type dopants can be P, As, Sb, or the like. In some embodiments, the p-type body region 206 may include higher dopant concentration than the p-type substrate 100.

Source regions 252 and 254 are disposed in the body region 206. In some embodiments, the source regions 252 and 254 may be heavily doped n-type region, and can also be referred to as heavily doped n-type (N+) regions 252 and 254. Drain regions 262 and 264 are disposed in the drift regions 202 and 204, respectively. In some embodiments, the drain regions 262 and 264 may be heavily doped n-type region, and can also be referred to as heavily doped n-type (N+) regions 262 and 264. A pick-up region 270 is disposed in the body region 206 and laterally between the source regions 252 and 254. In some embodiments, the pick-up region 270 may be in contact with the source regions 252 and 254. In some embodiments, the pick-up region 270 may be heavily doped p-type region, and can also be referred to as heavily doped p-type (P+) region 270.

In some embodiments, the source regions 252/254 and the drain regions 262/264 may include higher dopant concentration (e.g., n-type dopant concentration) than the drift regions 202 and 204. On the other hand, the pick-up region 270 may include higher dopant concentration (e.g., p-type dopant concentration) than the body region 206.

Gate structures 210A and 210B are disposed over the second region 100B of the substrate 100. In greater details, the gate structure 210A may cover portions of the drift region 202 and the body region 206. On the other hand, the gate structure 210B may cover portions of the drift region 204 and the body region 206. Each of the gate structures 210A and 210B may include a first gate dielectric 212, a second gate dielectric 214, and a gate electrode 216 over the first gate dielectric 212 and the second gate dielectric 214.

In some embodiments, the first gate dielectric 212 and the second gate dielectric 214 may include silicon oxide, silicon nitride, a high-k dielectric material, multi-layers thereof, or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

In some embodiments, the gate electrode 216 may include a conductive material such as doped polysilicon. In other embodiments, the gate electrode 216 may include metal-containing material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof.

Gate spacers 222 and 224 are disposed on opposite sidewalls of the gate structure 210A. Gate spacers 226 and 228 are disposed on opposite sidewalls of the gate structure 210B. In some embodiments, the gate spacers 222, 224, 226, and 228 may include silicon nitride-based material, such as SiN, SiON, SiCON or SiCN and combinations thereof, or any other suitable insulating material.

With respect to the gate structures 210A, the first gate dielectric 212 is laterally in contact with the second gate dielectric 214, in which the gate electrode 216 is in contact with both top surfaces of the first and second gate dielectrics 212 and 214. In some embodiments, the first gate dielectric 212 is thicker than the second gate dielectric 214 along the vertical direction (e.g., Z direction). That is, top surface of the first gate dielectric 212 is higher than top surface of the second gate dielectric 214. In some embodiments, bottom surface of the first gate dielectric 212 may be substantially level with bottom surface of the second gate dielectric 214. In some embodiments, the thickness of the first gate dielectric 212 is in a range from about 120 Å to about 130 Å. On the other hand, the thickness of the second gate dielectric 214 is in a range from about 70 Å to about 90 Å.

In order to get a lower threshold voltage (V_{T}) of the LS transistor Q2 (e.g., 0.7˜0.8V), the second gate dielectric 214 is thinned down to be 70 Å to about 90 Å for lower Vt from original thickness about 120 Å to about 130 Å, which is proportional to 100 mV/10 A. Because the drain voltage still keep the same (e.g., 12V in some embodiments), the gate edge will induce high electric field, which will result in induced impact-ionization and degradation, so a dual gate oxide structure is provided. For example, a thinner second gate dielectric 214 is provided for lower Vt device and a thicker first gate dielectric 212 is provided to reduce the edge impact ionization.

In some embodiments, the first gate dielectric 212 and the second gate dielectric 214 each has asymmetric sidewall profile. For example, the first gate dielectric 212 has a substantial vertical sidewall that is in contact with the gate spacer 222, and has an inclined sidewall that is in contact with the second gate dielectric 214. Similarly, the second gate dielectric 214 has a substantial vertical sidewall that is in contact with the gate spacer 224, and has an inclined sidewall that is in contact with the first gate dielectric 212. That is, the first gate dielectric 212 and the second gate dielectric 214 may form an inclined interface. In some embodiments, because the first gate dielectric 212 is thicker than the second gate dielectric 214, the inclined sidewall of the first gate dielectric 212 may be in contact with the gate electrode 216. The inclined sidewall of the first gate dielectric 212 may be beneficial to mitigate the gate electric field crowding at the top corner of the first gate dielectric 212, which potentially makes local channel early turn on. In some embodiments, the angle between the inclined sidewall of the first gate dielectric 212 and top surface of the substrate 100 (or top surface of the drift region 202) is in a range from about 30 degrees to about 60 degrees.

The drain region 262 is laterally separated from the gate spacer 222 by a non-zero distance. For example, the drain region 262 is laterally separated from the gate spacer 222 by a portion of the drift region 202. On the other hand, one side of the source region 252 may be vertically aligned with an outer sidewall of the gate spacer 224. That is, the source region 252 is closer to the gate structure 210A than the drain region 262.

The bottom surface of the first gate dielectric 212 has a lateral length E1. In some embodiments, the length E1 is in a range from about 0.10 μm to about 0.12 μm. The lateral length E2 between the first gate dielectric 212 and the drain region 262 is referred to as a “drift region length.” In some embodiments, the lateral length E2 is in a range from about 0.3 μm to about 0.6 μm. The second gate dielectric 214 may cover the body region 206 by a lateral length L1. In some embodiments, the lateral length L1 is in a range from about 0.1 μm to about 0.2 μm. The second gate dielectric 214 may also cover the drift region 202 by a lateral length L2. In some embodiments, the lateral length L2 is in a range from about 0.15 μm to about 0.25 μm. In some embodiments, the lateral length E1 depends on the voltage drop at opposites of the first gate dielectric 212, the drain voltage drop at one side of the first gate dielectric 212 close to the drain region 262 may be 5V and drain voltage drop at another side of the first gate dielectric 212 close to the source region 252 may be 3V, the lateral length E1 is selected to provide a good reliability of the first gate dielectric 212.

With respect to the gate structures 210B, in FIG. 3B, the gate structures 210B may include a symmetric profile as the gate structures 210A with respect to a center line of FIG. 3B. In some embodiments, the gate structures 210B may include a symmetric profile as the gate structures 210A with respect to the pick-up region 270. Accordingly, some structural details of the gate structures 210B may be not repeated for brevity.

The drain region 264 is laterally separated from the gate spacer 226 by a non-zero distance. For example, the drain region 264 is laterally separated from the gate spacer 226 by a portion of the drift region 204. On the other hand, one side of the source region 254 may be vertically aligned with an outer sidewall of the gate spacer 228. That is, the source region 254 is closer to the gate structure 210B than the drain region 264.

Protective layers 232 and 234 are disposed over the substrate 100. The protective layer 232 may extend from top surface of the gate structure 210A, through outer sidewall of the gate spacer 222, to top surface of the drift region 202. In some embodiments, the protective layer 232 may terminate prior to reaching the drain region 262. In other embodiments, the protective layer 232 may cover a portion of the drain region 262. Similarly, the protective layer 234 may extend from top surface of the gate structure 210B, through outer sidewall of the gate spacer 226, to top surface of the drift region 204. In some embodiments, the protective layer 234 may terminate prior to reaching the drain region 264. In other embodiments, the protective layer 234 may cover a portion of the drain region 264. In some embodiments, the protective layers 232 and 234 may be made of dielectric material, such as silicon oxide, silicon nitride, or the like. In some embodiments where the protective layers 232 and 234 are made of oxide, the protective layers 232 and 234 can also be referred to as resistive protective oxides (RPOs).

Silicide layers 240 are disposed over top surfaces of the gate structures 210A and 210B, top surfaces of the source regions 252 and 254, top surfaces of the drain regions 262 and 264, and top surface of the pick-up region 270. In some embodiments, silicide layers 240 may also extend to top surfaces of the drift regions 202 and 204. The silicide layers 240 may include metallic silicide. Examples of metallic silicide include tungsten silicide, titanium silicide, cobalt silicide, nickel silicide, platinum silicide, erbium silicide, or their combinations. In some embodiments, the silicide layers 240 may be omitted.

An interlayer dielectric (ILD) layer 120 is disposed over the substrate 100 and covering the gate structures 210A and 210B, the source regions 252 and 254, the drain regions 262 and 264, and the pick-up region 270. In some embodiments, the ILD layer 120 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

Contact plugs 281, 282, 283, 284, 285, 286, 287 are disposed in the ILD layer 120. In some embodiments, the contact plugs 281, 282, 283, 284, 285, 286, 287 are made of conductive material, such as metal. In some embodiments, the conductive material may include W, Ru, Co, Cu, Ti, TiN, Ta, TaN, Mo, Ni, or the like.

Contact plugs 281 are vertically over the gate structure 210A and are electrically connected to the gate structure 210A through the silicide layer 240. The contact plugs 281 can be referred to as gate contact plugs. In some embodiments, the contact plugs 281 are laterally arrange along a first direction (e.g., X direction). In the cross-sectional view of FIG. 3B, there are two contact plugs 281 arranged along the first direction and are vertically over the gate structure 210A. In some embodiments, the number of the contact plugs 281 is not limited thereto, and thus more or less contact plugs 281 may also be employed. In some embodiments where the silicide layers 240 are omitted, the contact plugs 281 may be in contact with top surface of the gate structure 210A.

Contact plugs 282 are vertically over the gate structure 210B and are electrically connected to the gate structure 210B through the silicide layer 240. The contact plugs 282 can be referred to as gate contact plugs. In some embodiments, the contact plugs 282 are laterally arrange along a first direction (e.g., X direction). In the cross-sectional view of FIG. 3B, there are two contact plugs 282 arranged along the first direction and are vertically over the gate structure 210B. In some embodiments, the number of the contact plugs 282 is not limited thereto, and thus more or less contact plugs 282 may also be employed. In some embodiments where the silicide layers 240 are omitted, the contact plugs 282 may be in contact with top surface of the gate structure 210B.

Contact plugs 283 are vertically over the source region 252 and are electrically connected to the source region 252 through the silicide layer 240. The contact plugs 283 can be referred to as source contact plugs. In some embodiments, the contact plugs 283 are laterally arrange along a second direction (e.g., Y direction). In the top view of FIG. 3A, there are five contact plugs 283 arranged along the second direction and are vertically over the source region 252. In some embodiments, the number of the contact plugs 283 is not limited thereto, and thus more or less contact plugs 283 may also be employed. In some embodiments where the silicide layers 240 are omitted, the contact plugs 283 may be in contact with top surface of the source region 252.

Contact plugs 284 are vertically over the source region 254 and are electrically connected to the source region 254 through the silicide layer 240. The contact plugs 284 can be referred to as source contact plugs. In some embodiments, the contact plugs 284 are laterally arrange along a second direction (e.g., Y direction). In the top view of FIG. 3A, there are five contact plugs 284 arranged along the second direction and are vertically over the source region 254. In some embodiments, the number of the contact plugs 284 is not limited thereto, and thus more or less contact plugs 284 may also be employed. In some embodiments where the silicide layers 240 are omitted, the contact plugs 284 may be in contact with top surface of the source region 254.

Contact plugs 285 are vertically over the drain region 262 and are electrically connected to the drain region 262 through the silicide layer 240. The contact plugs 285 can be referred to as drain contact plugs. In some embodiments, the contact plugs 285 are laterally arrange along a second direction (e.g., Y direction). In the top view of FIG. 3A, there are five contact plugs 285 arranged along the second direction and are vertically over the drain region 262. In some embodiments, the number of the contact plugs 285 is not limited thereto, and thus more or less contact plugs 285 may also be employed. In some embodiments where the silicide layers 240 are omitted, the contact plugs 285 may be in contact with top surface of the drain region 262.

Contact plugs 286 are vertically over the drain region 264 and are electrically connected to the drain region 264 through the silicide layer 240. The contact plugs 286 can be referred to as drain contact plugs. In some embodiments, the contact plugs 286 are laterally arrange along a second direction (e.g., Y direction). In the top view of FIG. 3A, there are five contact plugs 286 arranged along the second direction and are vertically over the drain region 264. In some embodiments, the number of the contact plugs 286 is not limited thereto, and thus more or less contact plugs 286 may also be employed. In some embodiments where the silicide layers 240 are omitted, the contact plugs 286 may be in contact with top surface of the drain region 264.

Contact plugs 287 are vertically over the pick-up region 270 and are electrically connected to the pick-up region 270 through the silicide layer 240. The contact plugs 287 can be referred to as pick-up contact plugs. In some embodiments, the contact plugs 287 are laterally arrange along a second direction (e.g., Y direction). In the top view of FIG. 3A, there are five contact plugs 287 arranged along the second direction and are vertically over the pick-up region 270. In some embodiments, the number of the contact plugs 287 is not limited thereto, and thus more or less contact plugs 287 may also be employed. In some embodiments where the silicide layers 240 are omitted, the contact plugs 287 may be in contact with top surface of the pick-up region 270.

In some embodiments, the number of the contact plugs 281 and the number of the contact plugs 282 may be the same. On the other hand, the number of the contact plugs 283, the number of the contact plugs 284, the number of the contact plugs 285, the number of the contact plugs 286, and the number of the contact plugs 287 may be the same. In some embodiments, the number of the contact plugs 281 and the number of the contact plugs 282 may be less than the number of the contact plugs 283, the number of the contact plugs 284, the number of the contact plugs 285, the number of the contact plugs 286, and the number of the contact plugs 287.

Metal lines 292 and 294 are disposed over the ILD layer 120. In some embodiments, the metal line 292 is in contact with top surfaces of the contact plugs 281, 282, 283, 284, and 287. That is, the metal line 292 is electrically connected to the gate structures 210A, 210B, the source regions 252, 254, and the pick-up region 270. Accordingly, the gate structures 210A, 210B, the source regions 252, 254, and the pick-up region 270 are electrically connected to each other. On the other hand, the metal line 294 is in contact with top surfaces of the contact plugs 285 and 286. That is, the metal line 294 is electrically connected to the drain regions 262 and 264. Accordingly, the drain regions 262 and 264 are electrically connected to each other. In some embodiments, the metal lines 292 and 294 are separated from each other. In some embodiments, the metal lines 292 and 294 are made of conductive material, such as metal. In some embodiments, the conductive material may include W, Ru, Co, Cu, Ti, TiN, Ta, TaN, Mo, Ni, or the like.

As shown in FIGS. 3A and 3B, the gate structure 210A, the source region 252, the drain region 262, the pick-up region 270, and the underlying drift region 202 and the body region 206 may collectively serve as a first transistor (e.g., a field effect transistor). Similarly, the gate structure 210B, the source region 254, the drain region 264, the pick-up region 270, and the underlying drift region 204 and the body region 206 may collectively serve as a second transistor (e.g., a field effect transistor). The gate structure 210A of the first transistor and the gate structure 210B of the second transistor are electrically connected to each other (e.g., through the metal line 292), the source region 252 of the first transistor and the source region 254 of the second transistor are electrically connected to each other (e.g., through the metal line 292), and the drain region 262 of the first transistor and the drain region 264 of the second transistor are electrically connected to each other (e.g., through the metal line 294). Moreover, the first and second transistors may include substantially the same configuration. The first and second transistors may be operated at the same time. Accordingly, the first and second transistors may equivalently function as the LS transistor Q2 as described in FIGS. 1 to 2B.

Stated another way, the LS transistor Q2 formed over the second region 100B of the substrate 100 can be regarded as having gate structures 210A and 210B, source regions 252 and 254, drain regions 262 and 264, and pick-up region 270. With respect to FIGS. 1, 3A, and 3B, the gate structures 210A and 210B can function as the gate G2 of the LS transistor Q2, the source regions 252 and 254 can function as the source S2 of the LS transistor Q2, the drain regions 262 and 264 can function as the drain D2 of the LS transistor Q2, and the pick-up region 270 (and/or the body region 206) can function as the body B2 of the LS transistor Q2.

However, in some other embodiments, one of the first and second transistors can be omitted. In some embodiments where the second transistor is omitted, the first transistor can individually function as the LS transistor Q2 as described in FIGS. 1 to 2B. Similarly, if the first transistor is omitted, the second transistor can individually function as the LS transistor Q2 as described in FIGS. 1 to 2B.

Reference is made to FIGS. 3A, 3C, 3D and 3E. The first region 100A of the substrate 100 may include a drift region 302, a drift region 304, and a body region 306 between the drift region 302 and the drift region 304. In some embodiments, the drift regions 302 and 304 may be doped with n-type dopants, and can also be referred to as n-type drift regions 302 and 304. On the other hand, the body region 306 may be doped with p-type dopants, and can also be referred to as p-type body region 306. Examples of p-type dopants can be B, Al, Ga, In, or the like. Examples of n-type dopants can be P, As, Sb, or the like. In some embodiments, the p-type body region 306 may include higher dopant concentration than the p-type substrate 100.

Source region 352 is disposed in the body region 306 (see FIGS. 3C and 3E). In some embodiments, the source region 352 may be heavily doped n-type region, and can also be referred to as heavily doped n-type (N+) region 352. Drain regions 362 and 364 are disposed in the drift regions 302 and 304, respectively. In some embodiments, the drain regions 362 and 364 may be heavily doped n-type region, and can also be referred to as heavily doped n-type (N+) regions 362 and 364.

A pick-up region 370 is disposed in the body region 306 (see FIGS. 3D and 3E). In some embodiments, the pick-up region 370 may be heavily doped p-type region, and can also be referred to as heavily doped p-type (P+) region 370.

As shown in the cross-sectional view of FIG. 3E, the source region 352 may include several portions 352A, 352B, and 352C, and the pick-up region 370 may include several portions 370A and 370B. In some embodiments, the portions 352A, 352B, and 352C of the source region 352 and the portions 370A and 370B of the pick-up region 370 are alternately arranged along a second direction (e.g., Y direction). Stated another way, the source region 352 and the pick-up region 370 are arranged along the second direction (e.g., Y direction). However, the source regions 252, 254 and the pick-up region 270 discussed in FIGS. 3A and 3B are alternately arranged along a first direction (e.g., X direction).

Gate structures 310A and 310B are disposed over the first region 100A of the substrate 100. In greater details, the gate structure 310A may cover portions of the drift region 302 and the body region 306. On the other hand, the gate structure 310B may cover portions of the drift region 304 and the body region 306. Each of the gate structures 310A and 310B may include a first gate dielectric 312, a second gate dielectric 314, and a gate electrode 316 over the first gate dielectric 312 and the second gate dielectric 314. Gate spacers 322 and 324 are disposed on opposite sidewalls of the gate structure 310A. Gate spacers 326 and 328 are disposed on opposite sidewalls of the gate structure 310B.

In some embodiments, the materials of the first gate dielectric 312, the second gate dielectric 314, and the gate electrode 316 may be the same or similar to the first gate dielectric 212, the second gate dielectric 214, the gate electrode 216 as described above, and thus relevant details will not be repeated for brevity. In some embodiments, the materials of gate spacers 322, 324, 326, and 328 may be the same or similar to the gate spacers 222, 224, 226, and 228 as described above, and thus relevant details will not be repeated for brevity.

With respect to the gate structures 310A, the first gate dielectric 312 is laterally in contact with the second gate dielectric 314, in which the gate electrode 316 is in contact with both top surfaces of the first and second gate dielectrics 312 and 314. In some embodiments, the first gate dielectric 312 is thicker than the second gate dielectric 314 along the vertical direction. That is, top surface of the first gate dielectric 312 is higher than top surface of the second gate dielectric 314. In some embodiments, bottom surface of the first gate dielectric 312 may be substantially level with bottom surface of the second gate dielectric 314. In some embodiments, the thickness of the first gate dielectric 312 is in a range from about 120 Å to about 130 Å. On the other hand, the thickness of the second gate dielectric 314 is in a range from about 70 Å to about 90 Å.

In some embodiments, the first gate dielectric 312 and the second gate dielectric 314 each has asymmetric sidewall profile. For example, the first gate dielectric 312 has a substantial vertical sidewall that is in contact with the gate spacer 322, and has an inclined sidewall that is in contact with the second gate dielectric 314. Similarly, the second gate dielectric 314 has a substantial vertical sidewall that is in contact with the gate spacer 324, and has an inclined sidewall that is in contact with the first gate dielectric 312. That is, the first gate dielectric 312 and the second gate dielectric 312 may form an inclined interface. In some embodiments, because the first gate dielectric 312 is thicker than the second gate dielectric 312, the inclined sidewall of the first gate dielectric 312 may be in contact with the gate electrode 316. The inclined sidewall of the first gate dielectric 312 may be beneficial to mitigate the gate electric field crowding at the top corner of the first gate dielectric 312, which potentially makes local channel early turn on. In some embodiments, the angle between the inclined sidewall of the first gate dielectric 312 and top surface of the substrate 100 (or top surface of the drift region 302) is in a range from about 30 degrees to about 60 degrees.

The drain region 362 is laterally separated from the gate spacer 322 by a non-zero distance. For example, the drain region 362 is laterally separated from the gate spacer 322 by a portion of the drift region 302. On the other hand, one side of the source region 352 may be vertically aligned with an outer sidewall of the gate spacer 324. That is, the source region 352 is closer to the gate structure 310A than the drain region 362.

With respect to the gate structures 310B, in FIGS. 3C and 3D, the gate structures 310B may include a symmetric profile as the gate structures 310A with respect to a center line of FIGS. 3C and 3D. In some embodiments, the gate structures 310B may include a symmetric profile as the gate structures 310A with respect to the source region 352 (see FIG. 3C) or with respect to the pick-up region 370 (see FIG. 3D). Accordingly, some structural details of the gate structures 310B may be not repeated for brevity.

The drain region 364 is laterally separated from the gate spacer 326 by a non-zero distance. For example, the drain region 364 is laterally separated from the gate spacer 326 by a portion of the drift region 304. On the other hand, another side of the source region 352 may be vertically aligned with an outer sidewall of the gate spacer 328. That is, the source region 352 is closer to the gate structure 310B than the drain region 264.

As shown in FIGS. 3B, 3C, and 3D, the distance between the gate structures 210A and 210B is greater than the distance between the gate structures 310A and 310B. This is because there are source regions 252, 254 and the pick-up region 270 between the gate structures 210A and 210B, while there is only a source region 352 (see FIG. 3C) or a pick-up region 370 (see FIG. 3D) between the gate structures 310A and 310B. Similarly, the distance between the gate spacers 224 and 228 is greater than the distance between the gate spacers 324 and 328. As a result, the area of the second region 100B of the substrate 100 may be greater than the area of the first region 100A of the substrate 100. In some embodiments, the area of the second region 100B of the substrate 100 may be greater than the area of the first region 100A of the substrate 100 by 2 to 3 times. In some embodiments, the distance between the pick-up region 270 and the gate structure 210A (or 210B) is greater than the distance between the pick-up region 370 and the gate structure 310A (or 310B).

Protective layers 332 and 334 are disposed over the substrate 100. The protective layer 332 may extend from top surface of the gate structure 310A, through outer sidewall of the gate spacer 322, to top surface of the drift region 302. In some embodiments, the protective layer 332 may terminate prior to reaching the drain region 362. In other embodiments, the protective layer 332 may cover a portion of the drain region 362. Similarly, the protective layer 334 may extend from top surface of the gate structure 310B, through outer sidewall of the gate spacer 326, to top surface of the drift region 304. In some embodiments, the protective layer 334 may terminate prior to reaching the drain region 364. In other embodiments, the protective layer 334 may cover a portion of the drain region 364.

Silicide layers 340 are disposed over top surfaces of the gate structures 310A and 310B, top surface of the source region 352, top surfaces of the drain regions 362 and 364, and top surface of the pick-up region 370. In some embodiments, silicide layers 340 may also extend to top surfaces of the drift regions 302 and 304. The silicide layers 340 may include metallic silicide. Examples of metallic silicide include tungsten silicide, titanium silicide, cobalt silicide, nickel silicide, platinum silicide, erbium silicide, or their combinations. In some embodiments, the silicide layers 340 may be omitted.

The interlayer dielectric (ILD) layer 120 is disposed over the substrate 100 and covering the gate structures 310A and 310B, the source region 352, the drain regions 362 and 364, and the pick-up region 370.

Contact plugs 381, 382, 383, 385, 386, 387 are disposed in the ILD layer 120. In some embodiments, the contact plugs 381, 382, 383, 385, 386, 387 are made of conductive material, such as metal. In some embodiments, the conductive material may include W, Ru, Co, Cu, Ti, TiN, Ta, TaN, Mo, Ni, or the like.

Contact plugs 381 are vertically over the gate structure 310A and are electrically connected to the gate structure 310A through the silicide layer 340. The contact plugs 381 can be referred to as gate contact plugs. In some embodiments, the contact plugs 381 are laterally arrange along a first direction (e.g., X direction). In the cross-sectional view of FIG. 3C, there are two contact plugs 381 arranged along the first direction and are vertically over the gate structure 310A. In some embodiments, the number of the contact plugs 381 is not limited thereto, and thus more or less contact plugs 381 may also be employed. In some embodiments where the silicide layers 340 are omitted, the contact plugs 381 may be in contact with top surface of the gate structure 310A.

Contact plugs 382 are vertically over the gate structure 310B and are electrically connected to the gate structure 310B through the silicide layer 340. The contact plugs 382 can be referred to as gate contact plugs. In some embodiments, the contact plugs 382 are laterally arrange along a first direction (e.g., X direction). In the cross-sectional view of FIG. 3C, there are two contact plugs 382 arranged along the first direction and are vertically over the gate structure 310B. In some embodiments, the number of the contact plugs 382 is not limited thereto, and thus more or less contact plugs 382 may also be employed. In some embodiments where the silicide layers 340 are omitted, the contact plugs 382 may be in contact with top surface of the gate structure 310B.

Contact plugs 383 are vertically over the source region 352 and are electrically connected to the source region 352 through the silicide layer 340. The contact plugs 383 can be referred to as source contact plugs. In some embodiments, the contact plugs 383 are laterally arrange along a second direction (e.g., Y direction). In the top view of FIG. 3A, there are three contact plugs 383 arranged along the second direction and are vertically over the source region 352. In some embodiments, the number of the contact plugs 383 is not limited thereto, and thus more or less contact plugs 383 may also be employed. In some embodiments where the silicide layers 340 are omitted, the contact plugs 383 may be in contact with top surface of the source region 352.

Contact plugs 385 are vertically over the drain region 362 and are electrically connected to the drain region 362 through the silicide layer 340. The contact plugs 385 can be referred to as drain contact plugs. In some embodiments, the contact plugs 385 are laterally arrange along a second direction (e.g., Y direction). In the top view of FIG. 3A, there are five contact plugs 385 arranged along the second direction and are vertically over the drain region 362. In some embodiments, the number of the contact plugs 385 is not limited thereto, and thus more or less contact plugs 385 may also be employed. In some embodiments where the silicide layers 340 are omitted, the contact plugs 385 may be in contact with top surface of the drain region 362.

Contact plugs 386 are vertically over the drain region 364 and are electrically connected to the drain region 364 through the silicide layer 340. The contact plugs 386 can be referred to as drain contact plugs. In some embodiments, the contact plugs 386 are laterally arrange along a second direction (e.g., Y direction). In the top view of FIG. 3A, there are five contact plugs 386 arranged along the second direction and are vertically over the drain region 364. In some embodiments, the number of the contact plugs 386 is not limited thereto, and thus more or less contact plugs 386 may also be employed. In some embodiments where the silicide layers 340 are omitted, the contact plugs 386 may be in contact with top surface of the drain region 364.

Contact plugs 387 are vertically over the pick-up region 270 and are electrically connected to the pick-up region 370 through the silicide layer 340 (see FIG. 3E). The contact plugs 387 can be referred to as pick-up contact plugs. In some embodiments, the contact plugs 387 are laterally arrange along a second direction (e.g., Y direction). Thus, in the top view of FIG. 3A, there are two contact plugs 387 arranged along the second direction and are vertically over the pick-up region 370. In some embodiments, the number of the contact plugs 387 is not limited thereto, and thus more or less contact plugs 387 may also be employed. In some embodiments where the silicide layers 340 are omitted, the contact plugs 387 may be in contact with top surface of the pick-up region 370. In FIGS. 3A and 3E, contact plugs 383 and contact plugs 387 are alternately arranged along the second direction (e.g., Y direction).

In some embodiments, the number of the contact plugs 381 and the number of the contact plugs 382 may be the same. On the other hand, the number of the contact plugs 385 and the number of the contact plugs 386 may be the same. In some embodiments, the number of the contact plugs 381 and the number of the contact plugs 382 may be less than the number of the contact plugs 385 and the number of the contact plugs 386. In some embodiments, the number of the contact plugs 383 may be less than the number of the contact plugs 385 and the number of the contact plugs 386. In some embodiments, the number of the contact plugs 387 may be less than the number of the contact plugs 383.

Metal lines 392, 393 and 394 are disposed over the ILD layer 120. In some embodiments, the metal line 392 is in contact with top surfaces of the contact plugs 381 and 382. That is, the metal line 392 is electrically connected to the gate structures 310A and 310B. Accordingly, the gate structures 310A and 310B are electrically connected to each other. The metal line 393 is in contact with top surfaces of the contact plugs 383 and 387. That is, the metal line 393 is electrically connected to the source region 352 and the pick-up region 370. Accordingly, the source region 352 and the pick-up region 370 are electrically connected to each other. On the other hand, the metal line 394 is in contact with top surfaces of the contact plugs 385 and 386. That is, the metal line 394 is electrically connected to the drain regions 362 and 364. Accordingly, the drain regions 362 and 364 are electrically connected to each other. In some embodiments, the metal lines 392, 393 and 394 are separated from each other. In some embodiments, the metal lines 392, 393 and 394 are made of conductive material, such as metal. In some embodiments, the conductive material may include W, Ru, Co, Cu, Ti, TiN, Ta, TaN, Mo, Ni, or the like.

As shown in FIGS. 3A, 3C, 3D, and 3E, the gate structure 310A, the source region 352, the drain region 362, the pick-up region 370, and the underlying drift region 302 and the body region 306 may collectively serve as a third transistor (e.g., a field effect transistor). Similarly, the gate structure 310B, the source region 352, the drain region 362, the pick-up region 370, and the underlying drift region 304 and the body region 306 may collectively serve as a fourth transistor (e.g., a field effect transistor). The gate structure 310A of the third transistor and the gate structure 310B of the fourth transistor are electrically connected to each other (e.g., through the metal line 392), and the drain region 362 of the third transistor and the drain region 364 of the fourth transistor are electrically connected to each other (e.g., through the metal line 394). The third and fourth transistors may share a same source region 352 and a same pick-up region 370. The third and fourth transistors may include substantially the same configuration. The third and fourth transistors may be operated at the same time. Accordingly, the third and fourth transistors may equivalently function as the HS transistor Q1 as described in FIGS. 1 to 2B.

Stated another way, the HS transistor Q1 formed over the first region 100A of the substrate 100 can be regarded as having gate structures 310A and 310B, source region 352, drain regions 362 and 364, and pick-up region 370. With respect to FIGS. 1, 3A, 3B, 3D, and 3E, the gate structures 310A and 310B can function as the gate G1 of the HS transistor Q1, the source region 352 can function as the source S1 of the HS transistor Q1, the drain regions 362 and 364 can function as the drain region D1 of the HS transistor Q1, and the pick-up region 370 (and/or the body region 306) can function as the body B1 of the HS transistor Q1.

However, in some other embodiments, one of the third and fourth transistors can be omitted. In some embodiments where the fourth transistor is omitted, the third transistor can individually function as the HS transistor Q1 as described in FIGS. 1 to 2B. Similarly, if the third transistor is omitted, the fourth transistor can individually function as the HS transistor Q1 as described in FIGS. 1 to 2B.

In some embodiments of the present disclosure, during the operation of the converter 10, the turn-on time of the LS transistor Q2 may be >80% of duty cycle. To effectively increase the channel area of the LS transistor Q2, the pick-up region 270 is disposed laterally separated from the gate structures 210A and 210B by the source regions 252 and 254, respectively. Moreover, by shorting gate/bulk/source together for the LS transistor Q2, it will increase 10˜20% W/L which means we keep Cg or Qg and reduced Rsp for the LS transistor Q2.

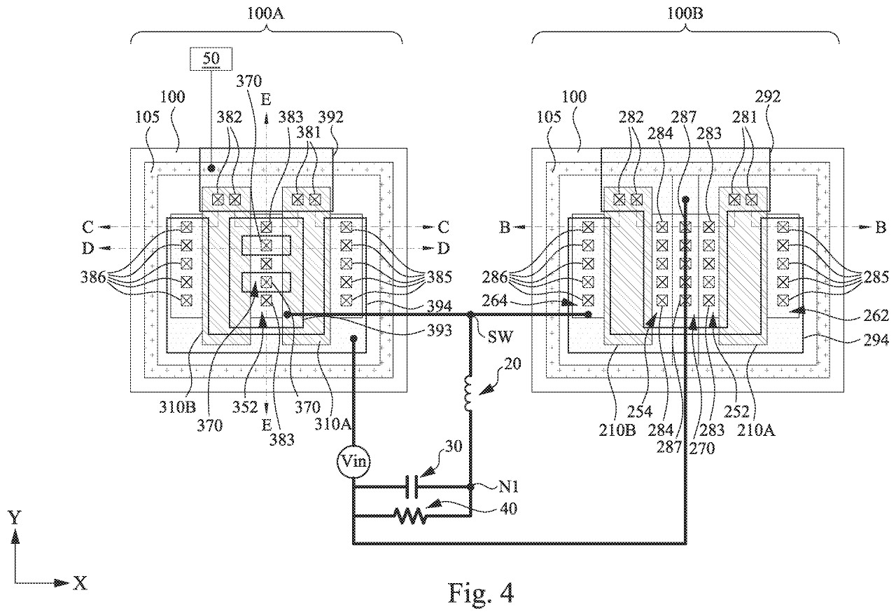

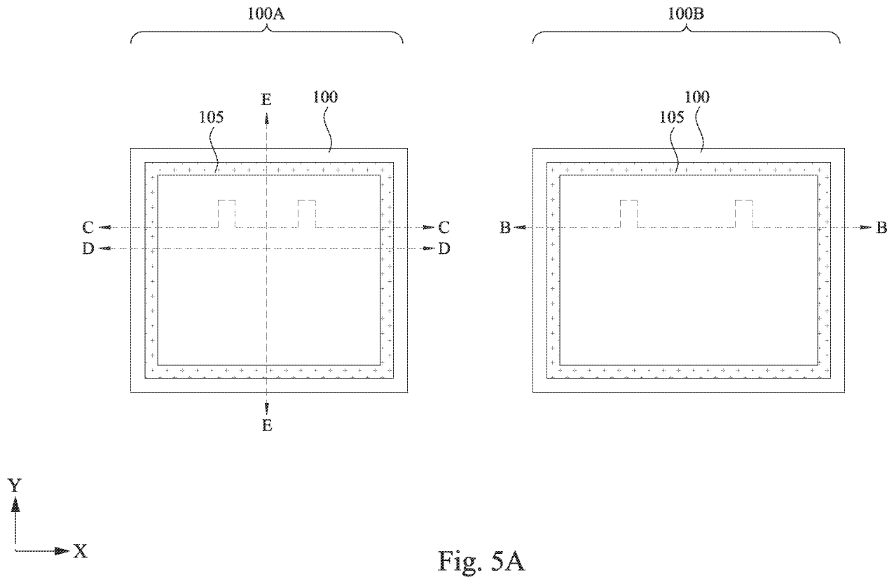

FIG. 4 illustrates a top view of a converter in accordance with some embodiments of the present disclosure. The metal line 394 is electrically connected to a supply voltage terminal Vin. That is, the supply voltage terminal Vin is electrically connected to the drain regions 362 and 364. Stated another way, the supply voltage terminal Vin is electrically connected to the drain D1 of the HS transistor Q1 (see FIG. 1).

The metal line 392 is electrically connected to a driver 50. That is, the driver 50 is electrically connected to the gate structures 310A and 310B. Stated another way, the driver 50 is electrically connected to the gate of the HS transistor Q1.

The metal line 393 and the metal line 294 are electrically connected to each other. That is, the source region 352 and the pick-up region 370 are electrically connected to the drain regions 262 and 264. Stated another way, the source S1 and the body B1 of the HS transistor Q1 are electrically connected to the drain D2 of the LS transistor Q2 (see FIG. 1).

In some embodiments, the metal line 393 and the metal line 294 are electrically connected to a node SW. An inductor 20 is electrically connected to the node SW. That is, the inductor 20 is electrically connected to the source region 352, the pick-up region 370, and the drain regions 362 and 364. Stated another way, the inductor 20 is electrically connected to the source S1 and the body B1 of the HS transistor Q1 and the drain D2 of the LS transistor Q2 (see FIG. 1).

Another side of the inductor 20 is electrically connected to a node N1. One side of each of the capacitor 30 and the resistor 40 is electrically connected to the node N1. Another side of each of the capacitor 30 and the resistor 40 is also electrically connected to the metal line 292. That is, the capacitor 30 and the resistor 40 are electrically connected to the gate structures 210A, 210B, the source regions 252, 254, the pick-up region 270. Stated another way, the capacitor 30 and the resistor 40 are electrically connected to the gate G2, source S2, and body B2 of the LS transistor Q2.

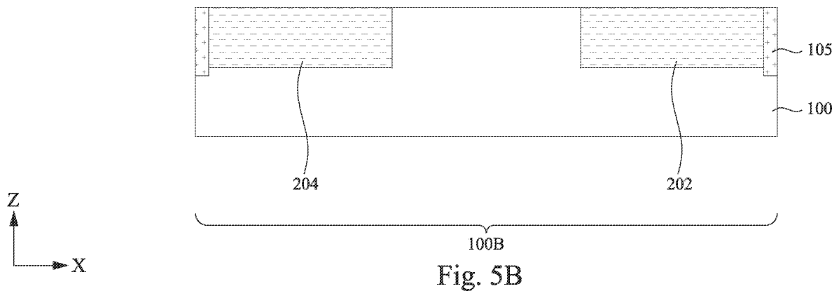

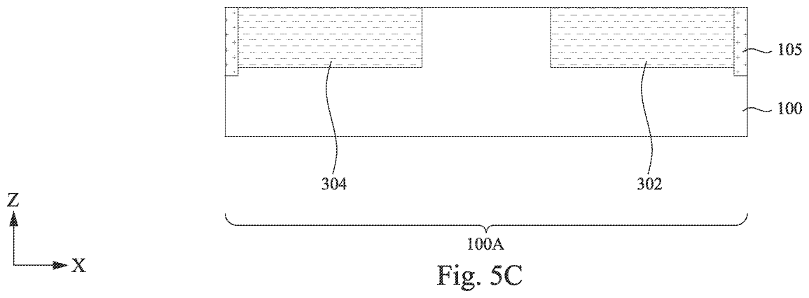

FIGS. 5A to 18E are schematic views of a converter in various stages of fabrication in accordance with some embodiments of the present disclosure. Although the views shown in FIGS. 5A to 18E are described with reference to a method, it will be appreciated that the structures shown in FIGS. 5A to 18E are not limited to the method but rather may stand alone separate of the method. Although FIGS. 5A to 18E are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. In some embodiments, some elements described in FIGS. 5A to 18E may be similar to the same as those described with respect to FIGS. 1 to 4, such elements are labeled the same and relevant details will not be repeated for brevity.

Reference is made to FIGS. 5A to 5C, in which FIG. 5B is a cross-sectional view along line B-B of FIG. 5A, and FIG. 5C is a cross-sectional view along line C-C of FIG. 5A. A substrate 100 is provided. Isolation structures 105 are formed in the substrate 100. In some embodiments, the isolation structures 105 may be formed by, for example, etching the substrate 100 to form trenches, depositing a dielectric material over the substrate 100 and filling the trenches, and then performing a planarization process (e.g., a chemical mechanism polishing; CMP) to remove excess dielectric material until top surface of the substrate 100 is exposed.

Drift regions 202, 204, 302, and 304 are formed in the substrate 100. In greater details, the drift regions 302 and 304 are formed in the first region 100A of the substrate 100, and the drift regions 202 and 204 are formed in the second region 100B of the substrate 100. In some embodiments, the drift regions 202, 204, 302, and 304 may be formed by, for example, forming a patterned mask having openings exposing the substrate 100, performing an ion implantation process to the substrate 100 through the openings of the patterned mask, and then removing the patterned mask after the ion implantation process is performed. In some embodiments, the ion implantation process may include using n-type dopants, such as arsenic, phosphorous or other suitable n-type dopants.

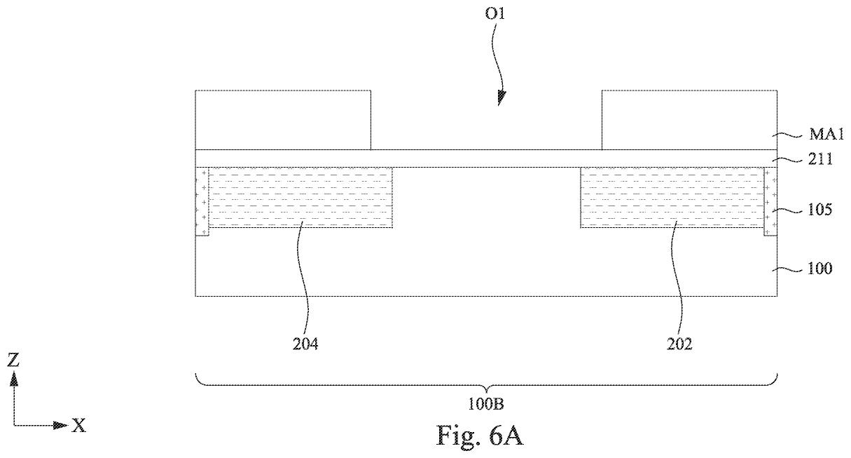

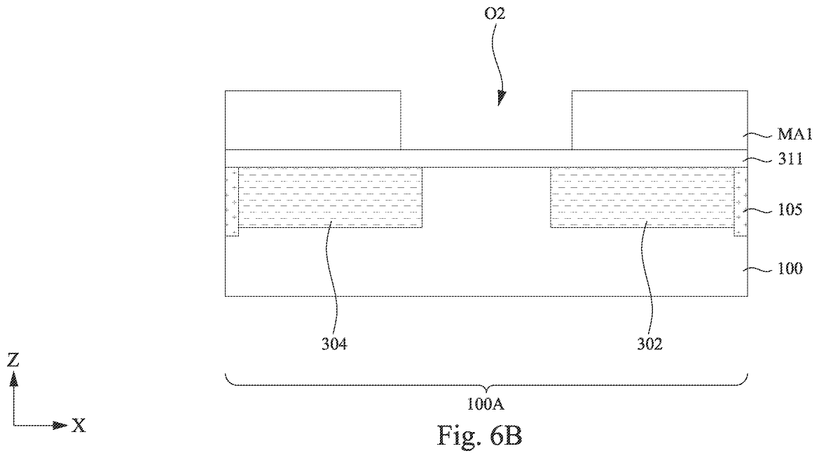

Reference is made to FIGS. 6A and 6B, in which FIGS. 6A and 6B follow the cross-sectional views of FIGS. 5B and 5C, respectively. A gate dielectric layer 311 and a gate dielectric layer 211 are formed over the first region 100A and the second region 100B of the substrate 100, respectively. In some embodiments, the gate dielectric layer 311 and the gate dielectric layer 211 are different portions of a continuous layer, and thus the gate dielectric layers 211 and 311 may include substantially the same thickness. In some embodiments, the gate dielectric layers 211 and 311 are formed by thermal oxidation, physical vapor deposition (PVD), chemical vapor deposition (CVD), atomic layer deposition (ALD), an epitaxial process or another suitable formation process. In some embodiments, the gate dielectric layers 211 and 311 are formed by dry or wet oxidation at a temperature in a range from about 850° C. to about 950° C.

A patterned mask MA1 is formed over the substrate 100 and covering the gate dielectric layers 211 and 311. The patterned mask MA1 may include an opening O1 exposing a portion of the gate dielectric layer 211 and an opening O2 exposing a portion of the gate dielectric layer 311. In some embodiments, the patterned mask MA1 may include photoresist, and may be patterned using suitable lithography process.

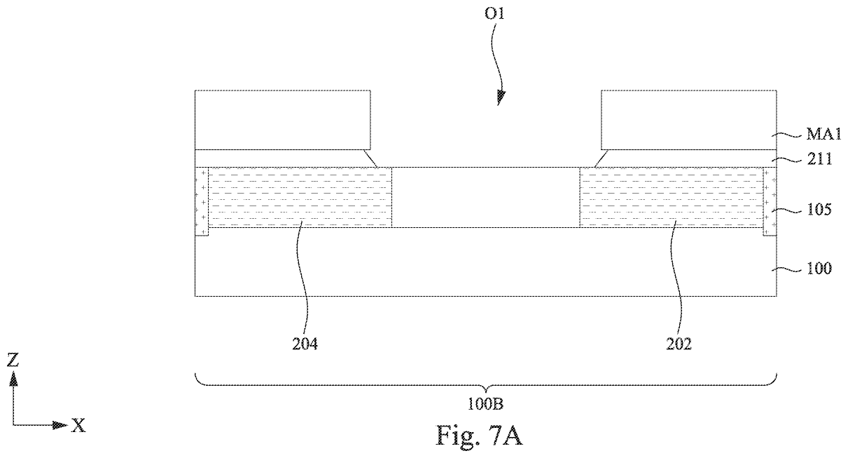

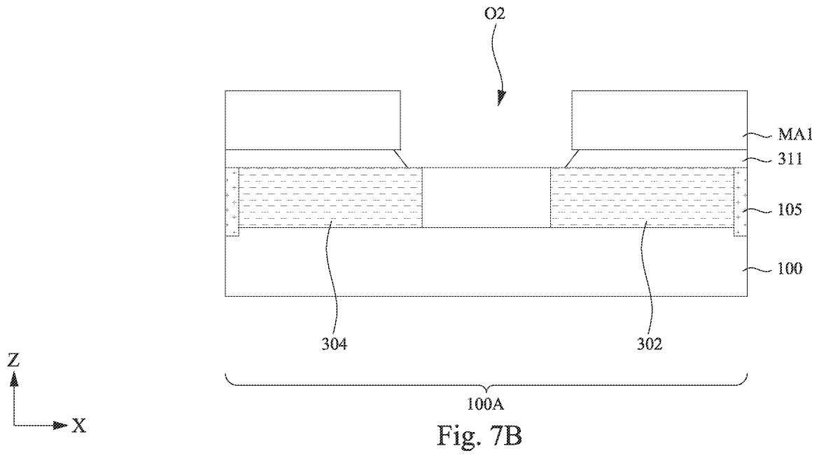

Reference is made to FIGS. 7A and 7B, in which FIGS. 7A and 7B follow the cross-sectional views of FIGS. 6A and 6B, respectively. An etching process is performed to remove exposed portions of the gate dielectric layers 211 and 311, such that top surface of the substrate 100 is exposed. In some embodiments, the etching process may include dry etch, wet etch, or combinations thereof. In some embodiments, the etching process may include an isotropic etching process, such as isotropic wet etch or isotropic dry etch, which will result in that the remaining gate dielectric layers 211 and 311 having inclined sidewalls exposed to the openings O1 and O2, respectively.

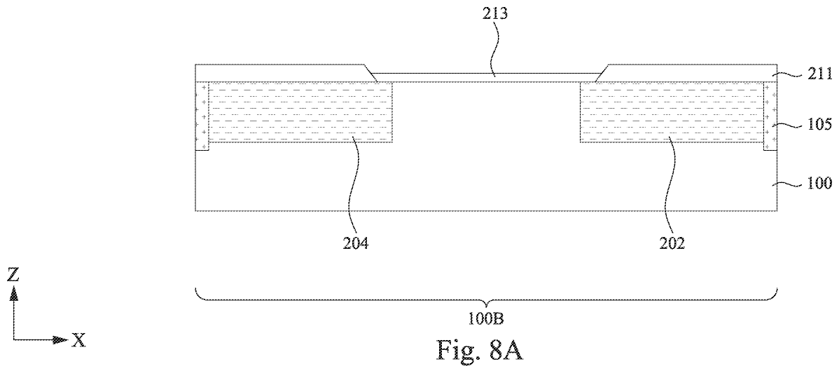

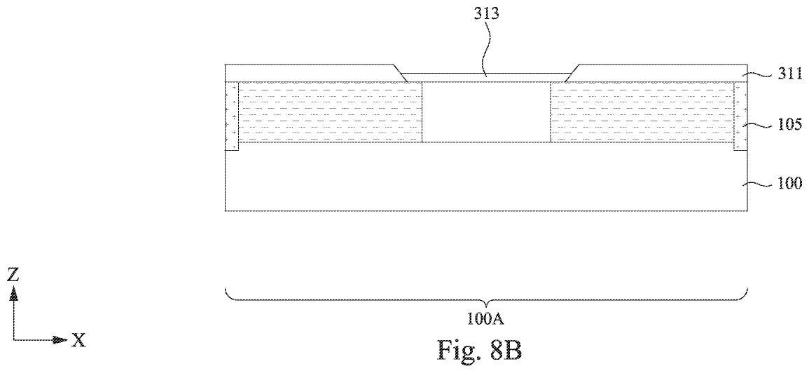

Reference is made to FIGS. 8A and 8B, in which FIGS. 8A and 8B follow the cross-sectional views of FIGS. 7A and 7B, respectively. The patterned mask MA1 is removed. A gate dielectric layer 213 and a gate dielectric layer 313 are formed over the exposed surfaces of the second region 100B and the first region 100A of the substrate 100, respectively. In some embodiments, the gate dielectric layers 213 and 313 are formed through a same deposition process, and thus may include substantially a same thickness. In some embodiments, the gate dielectric layers 213 and 313 are formed by thermal oxidation, physical vapor deposition (PVD), chemical vapor deposition (CVD), atomic layer deposition (ALD), an epitaxial process or another suitable formation process.

In some embodiments where the gate dielectric layers 213 and 313 are formed by thermal oxidation, the gate dielectric layers 213 and 313 may be selectively formed on the exposed surfaces of the substrate 100 without being formed over the gate dielectric layers 211 and 311. In some embodiments, the gate dielectric layers 213 and 313 are formed by dry or wet oxidation at a temperature in a range from about 750° C. to about 850° C. In some embodiments, the gate dielectric layers 213 and 313 may be deposited under a lower temperature and shorter deposition duration than the gate dielectric layers 211 and 311, such that the gate dielectric layers 213 and 313 may be thinner than the gate dielectric layers 211 and 311.

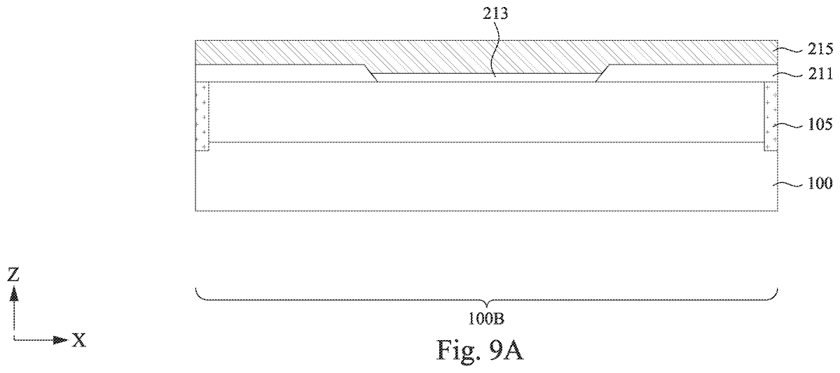

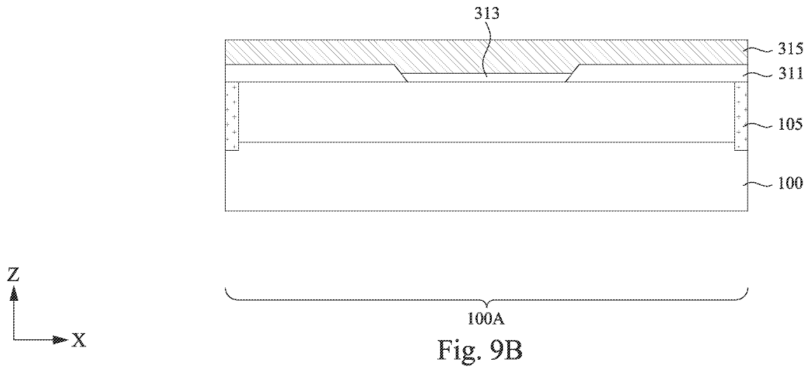

Reference is made to FIGS. 9A and 9B, in which FIGS. 9A and 9B follow the cross-sectional views of FIGS. 8A and 8B, respectively. A gate electrode layer 215 and a gate electrode layer 315 are formed over the substrate 100, respectively. In greater details, the gate electrode layer 215 may cover the gate dielectric layers 211 and 213, and the gate electrode layer 315 may cover the gate dielectric layers 311 and 313. In some embodiments, the gate electrode layers 215 and 315 are different portions of a continuous layer. In some embodiments, the gate electrode layers 215 and 315 are formed by, physical vapor deposition (PVD), chemical vapor deposition (CVD), atomic layer deposition (ALD), or another suitable formation process.

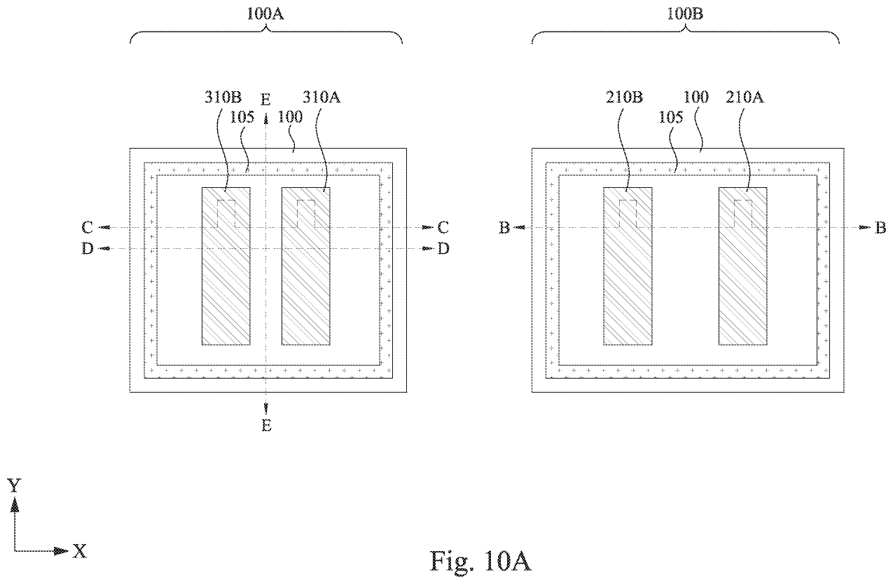

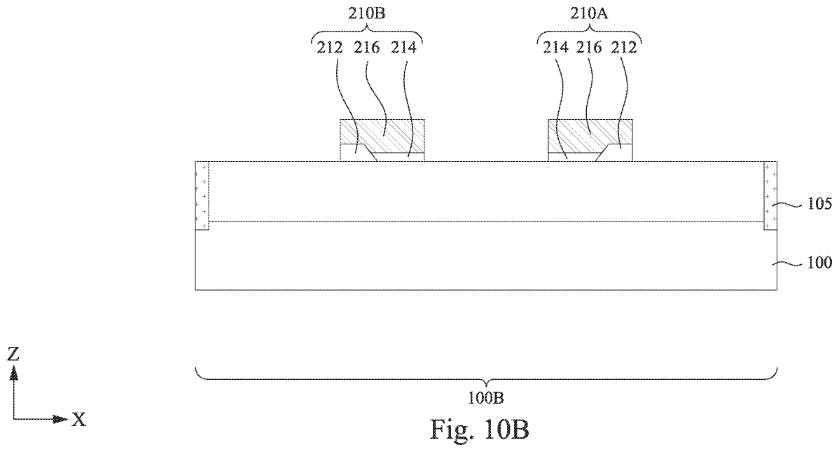

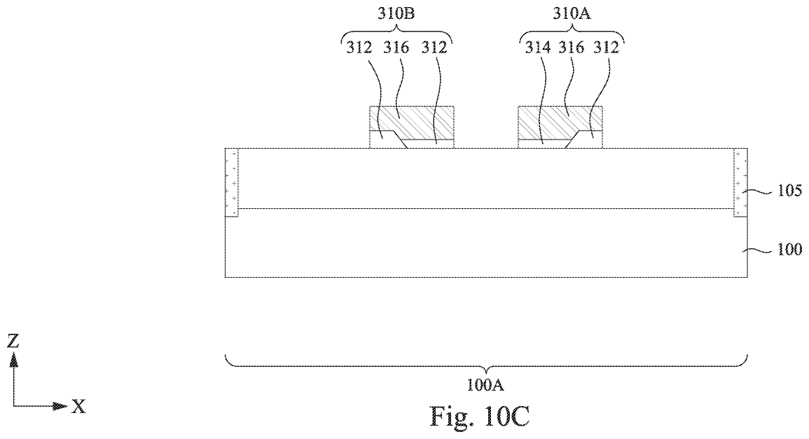

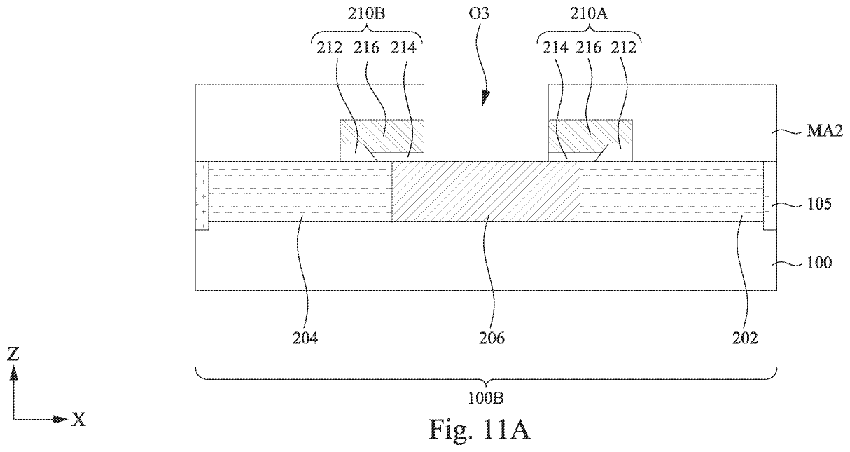

Reference is made to FIGS. 10A to 10C, in which FIG. 10B is a cross-sectional view along line B-B of FIG. 10A, and FIG. 10C is a cross-sectional view along line C-C of FIG. 10A. A patterning process is performed to the gate electrode layers 215, 315, the gate dielectric layers 211, 311, 213, 313 to form gate structures 210A, 210B, 310A, and 310B. In some embodiments, the patterning process may be performed by, for example, forming a patterned mask over the gate electrode layers 215 and 315, the patterned mask defining the positions and shapes of the gate structures 210A, 210B, 310A, and 310B. An etching process is performed to remove unwanted portions of the gate electrode layers 215, 315, and the gate dielectric layers 211, 311, 213, 313 that are uncovered by the patterned mask. The remaining portions of the gate dielectric layer 211, the gate dielectric layer 213, and the gate electrode layers 215 are referred to as gate dielectric 212, gate dielectric 214, and gate electrode 216, respectively. The remaining portions of the gate dielectric layer 311, the gate dielectric layer 313, and the gate electrode layers 315 are referred to as gate dielectric 312, gate dielectric 314, and gate electrode 316, respectively.

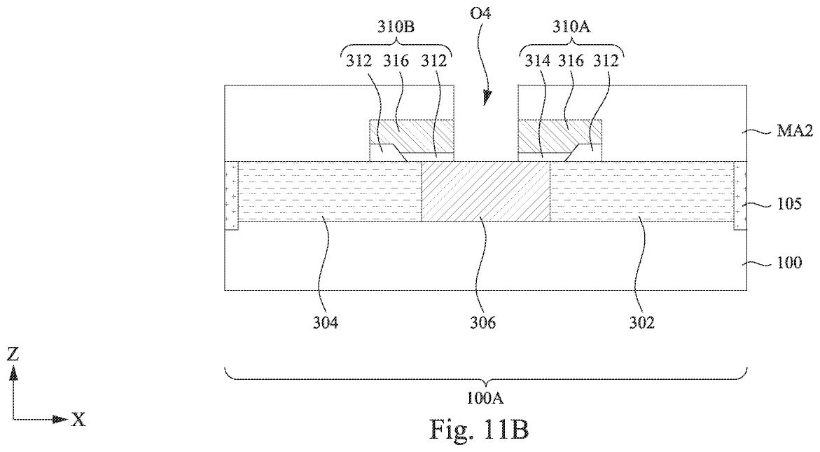

Reference is made to FIGS. 11A and 11B, in which FIGS. 11A and 11B follow the cross-sectional views of FIGS. 10B and 10C, respectively. A patterned mask MA2 is formed over the substrate 100. The patterned mask MA2 may include an opening O3 exposing a portion of the substrate 100 between the gate structures 210A and 210B, and an opening O4 exposing a portion of the substrate 100 between the gate structures 310A and 310B. An ion implantation process to the substrate 100 through the openings O3 and O4 of the patterned mask MA2, so as to form body regions 206 and 306 in the second region 100B and the first region 100A of the substrate 100, respectively. In some embodiments, the ion implantation process may include using p-type dopants, such as boron or BF2, or other suitable p-type dopants. In some embodiments, the patterned mask MA2 may include photoresist, and may be patterned using suitable lithography process.

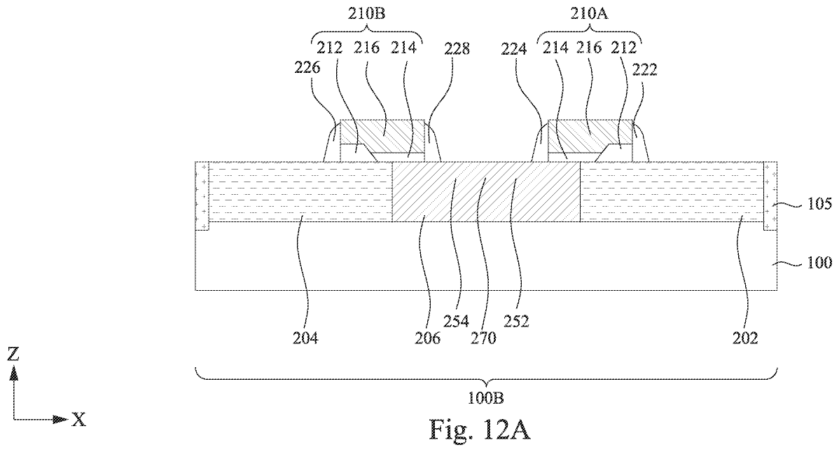

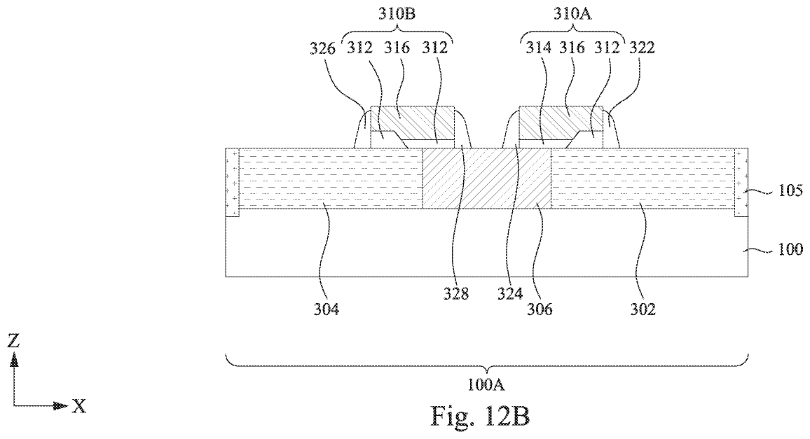

Reference is made to FIGS. 12A and 12B, in which FIGS. 12A and 12B follow the cross-sectional views of FIGS. 11A and 11B, respectively. After the body regions 206 and 306 are formed, the patterned mask MA2 is removed. Gate spacers 222 and 224 are formed on opposite sidewalls of the gate structure 210A. Gate spacers 226 and 228 are formed on opposite sidewalls of the gate structure 210B. Gate spacers 322 and 324 are formed on opposite sidewalls of the gate structure 310A. Gate spacers 326 and 328 are formed on opposite sidewalls of the gate structure 310B. In some embodiments, the gate spacers 222, 224, 226, 228, 322, 324, 326, and 328 may be formed by, for example, depositing a spacer layer blanket over the substrate 100, performing an anisotropic etching process to remove horizontal portions of the spacer layer, while leaving vertical portions of the spacer layer on sidewalls of the gate structures 210A, 210B, 310A, and 310B.

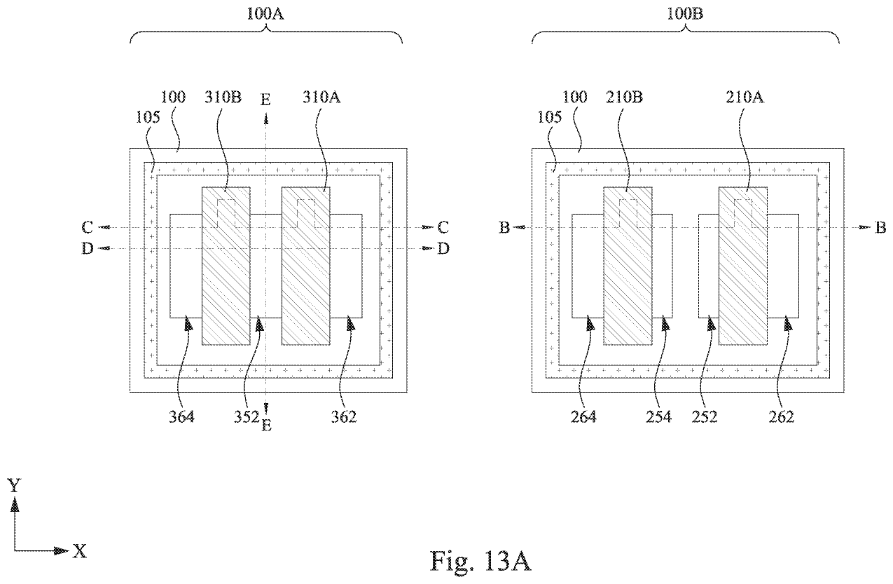

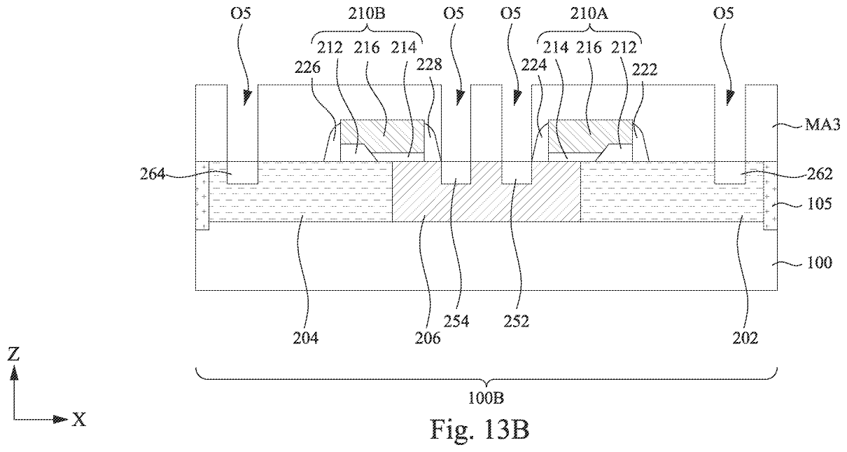

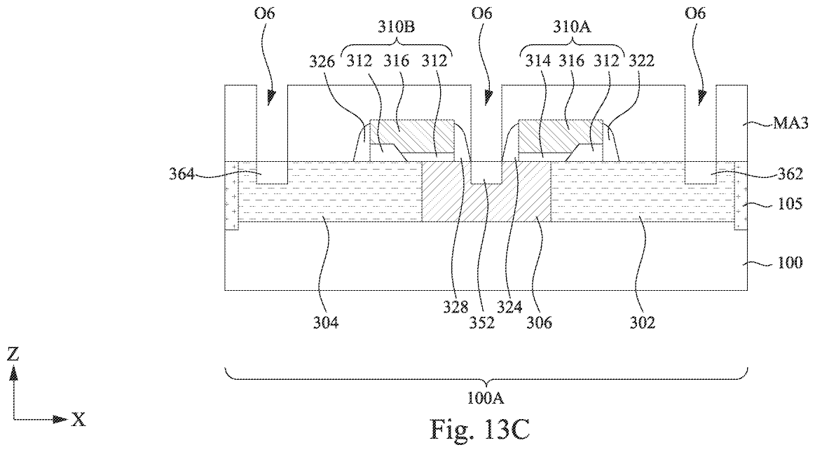

Reference is made to FIGS. 13A to 13C, in which FIG. 13B is a cross-sectional view along line B-B of FIG. 13A, and FIG. 13C is a cross-sectional view along line C-C of FIG. 13A. A patterned mask MA3 is formed over the substrate 100. The patterned mask MA3 may include openings O5 exposing portions of the second region 100B of the substrate 100, and openings O6 exposing portions of the first region 100A of the substrate 100. An ion implantation process to the substrate 100 through the openings O5 and O6 of the patterned mask MA3, so as to form source regions 252, 254, and 352 and drain regions 262, 264, 362, and 364. In some embodiments, the ion implantation process may include using n-type dopants, such as arsenic, phosphorous or other suitable n-type dopants. In some embodiments, the patterned mask MA3 may include photoresist, and may be patterned using suitable lithography process. Is it noted that the patterned mask MA3 is not illustrated in the top view of FIG. 13A for brevity.

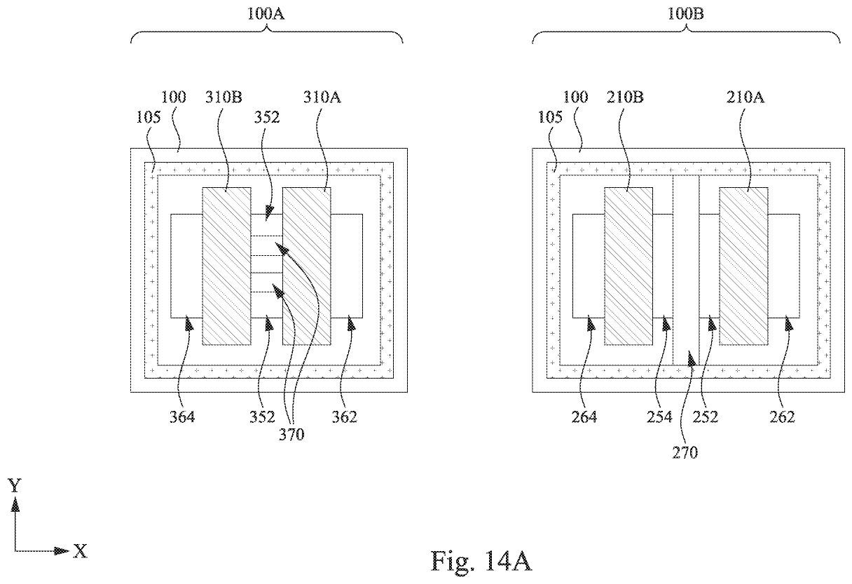

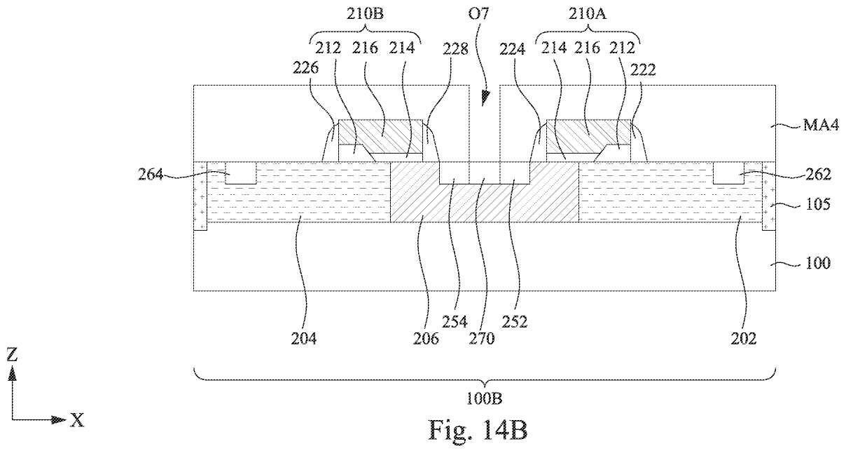

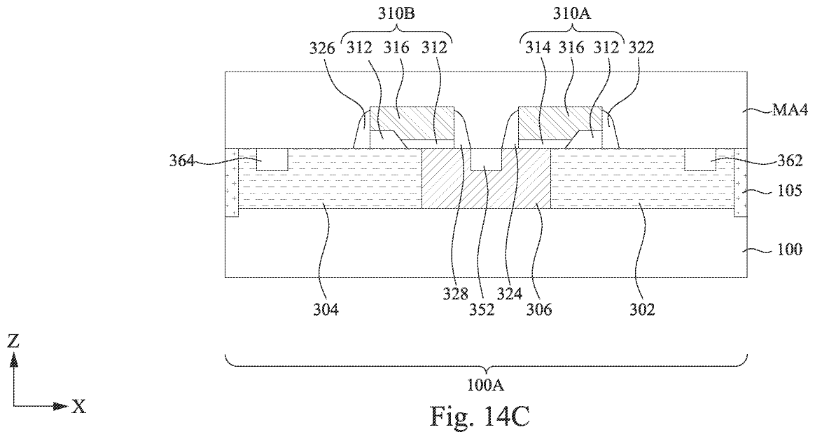

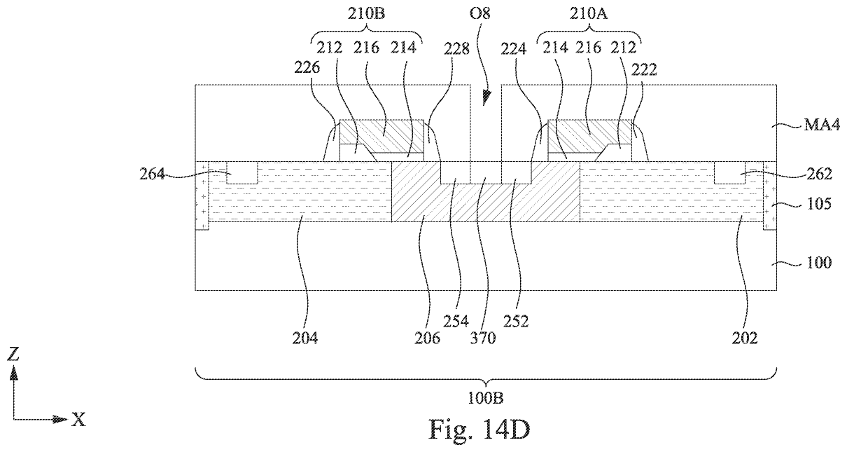

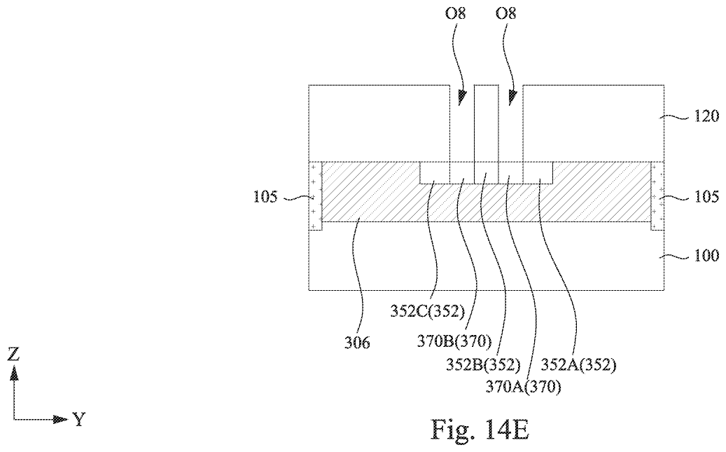

Reference is made to FIGS. 14A to 14E, in which FIG. 14B is a cross-sectional view along line B-B of FIG. 14A, and FIG. 14C is a cross-sectional view along line C-C of FIG. 14A, FIG. 14D is a cross-sectional view along line D-D of FIG. 14A, and FIG. 14E is a cross-sectional view along line E-E of FIG. 14A. After the source regions 252, 254, and 352 and the drain regions 262, 264, 362, and 364 are formed, the patterned mask MA3 is removed. A patterned mask MA4 is formed over the substrate 100. The patterned mask MA4 may include an opening O7 exposing a portion of the second region 100B of the substrate 100, and openings O8 exposing portions of the first region 100A of the substrate 100. In some embodiments, the source regions 252, 254, and 352 and the drain regions 262, 264, 362, and 364 may be covered by the patterned mask MA4. An ion implantation process to the substrate 100 through the openings O7 and O8 of the patterned mask MA4, so as to form pick-up regions 270 and 370. In some embodiments, the ion implantation process may include using p-type dopants, such as boron or BF2, or other suitable p-type dopants. In some embodiments, the patterned mask MA4 may include photoresist, and may be patterned using suitable lithography process. Is it noted that the patterned mask MA4 is not illustrated in the top view of FIG. 14A for brevity.

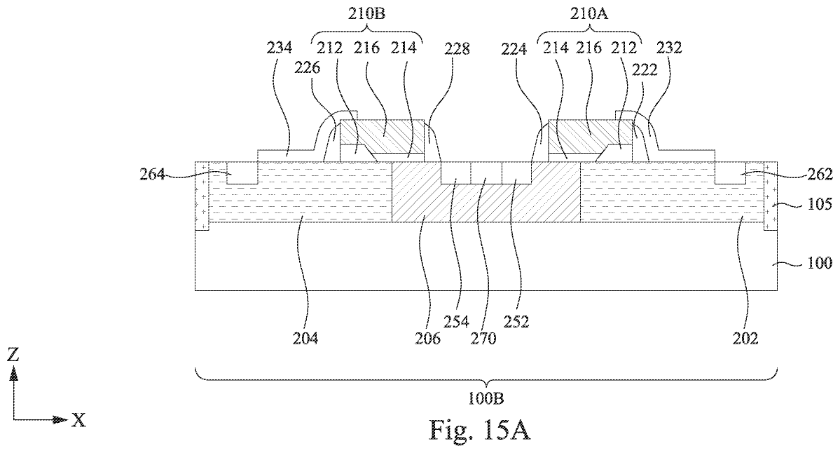

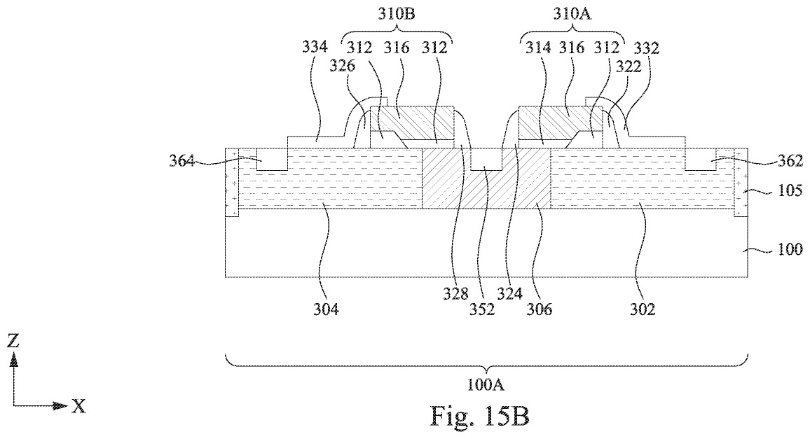

Reference is made to FIGS. 15A and 15B, in which FIGS. 15A and 15B follow the cross-sectional views of FIGS. 14B and 14C, respectively. After the pick-up regions 270 and 370 are formed, the patterned mask MA4 is removed. Protective layers 232 and 234 are formed over the substrate 100. In some embodiments, the protective layers 232 and 234 can be formed by, for example, depositing a dielectric layer blanket over the substrate 100, and then performing a lithography process to remove unwanted portions of the dielectric layer.

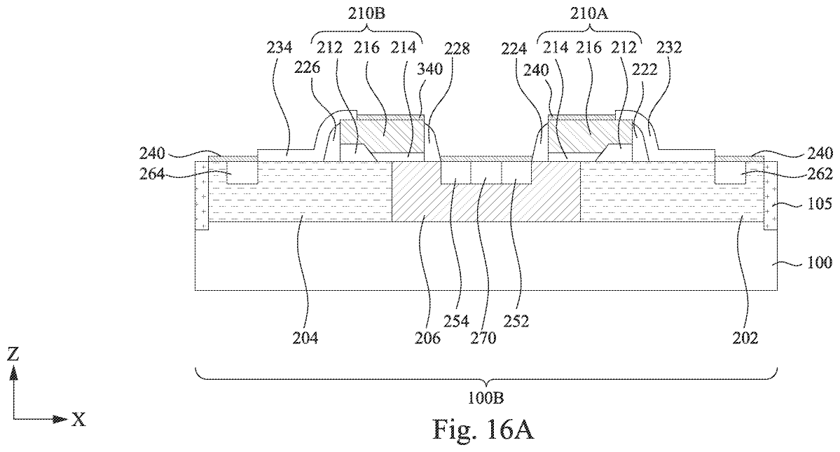

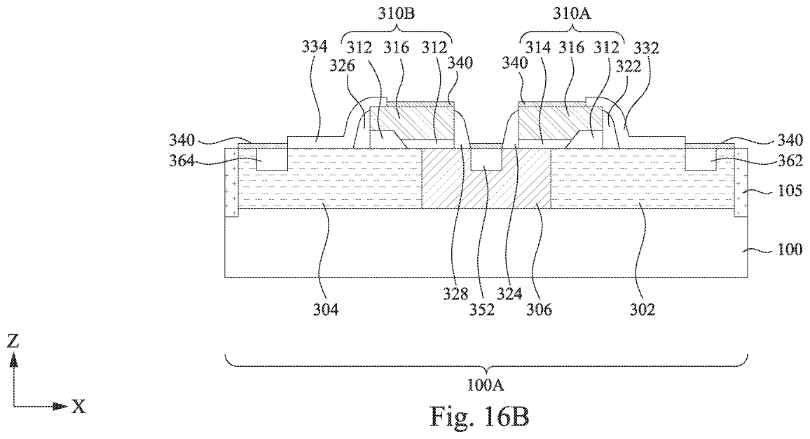

Reference is made to FIGS. 16A and 16B, in which FIGS. 16A and 16B follow the cross-sectional views of FIGS. 15A and 15B, respectively. One or more salicidation processes are performed to form silicide layers 240 and 340 on upper surfaces of the gate structures 210A, 210B, 310A, and 310B, source regions 252, 254, and 352, drain regions 262, 264, 362, and 364, and pick-up regions 270 and 370. In some embodiments, the salicidation process may be performed by depositing a metal material, such as nickel or cobalt, and then performing a thermal annealing process (e.g., a rapid thermal anneal).

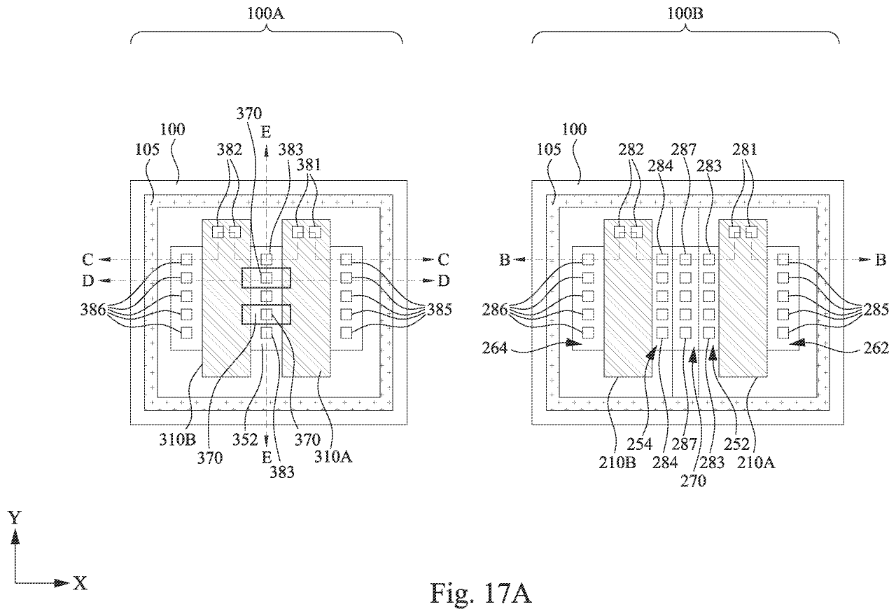

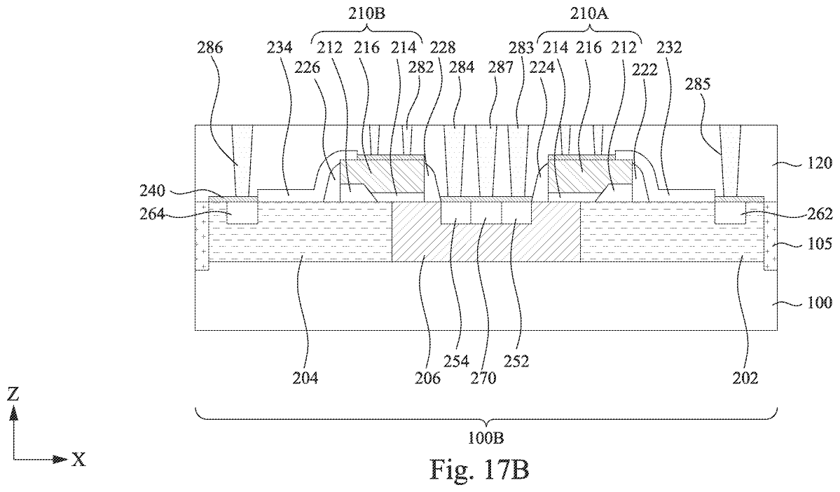

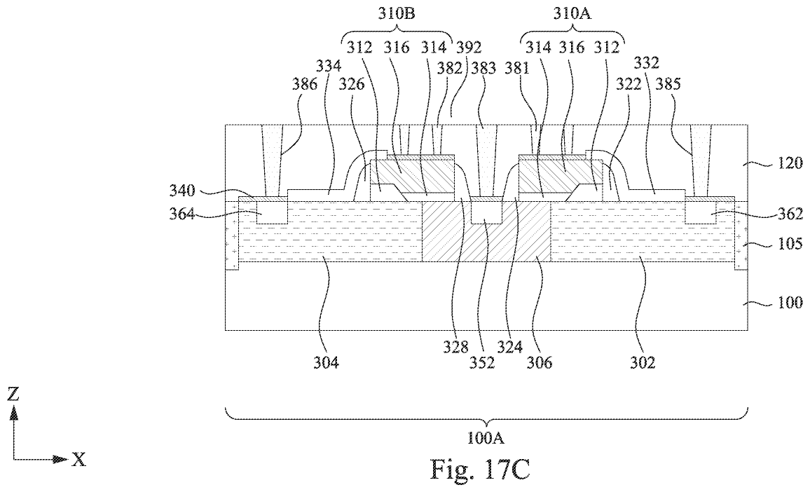

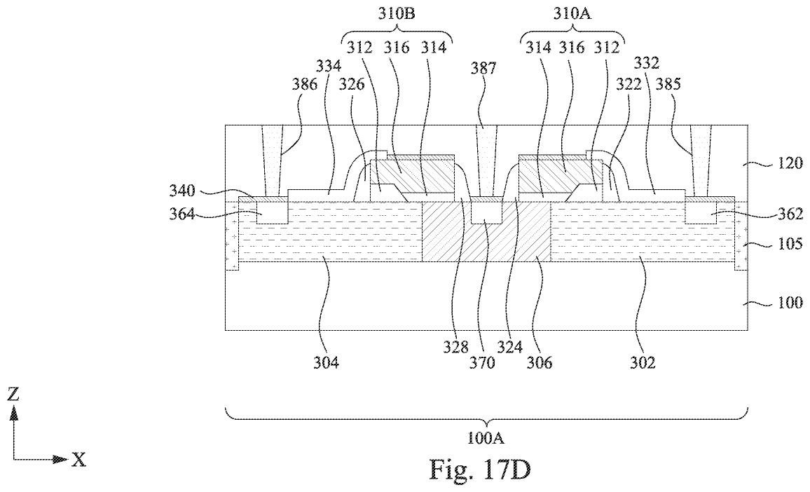

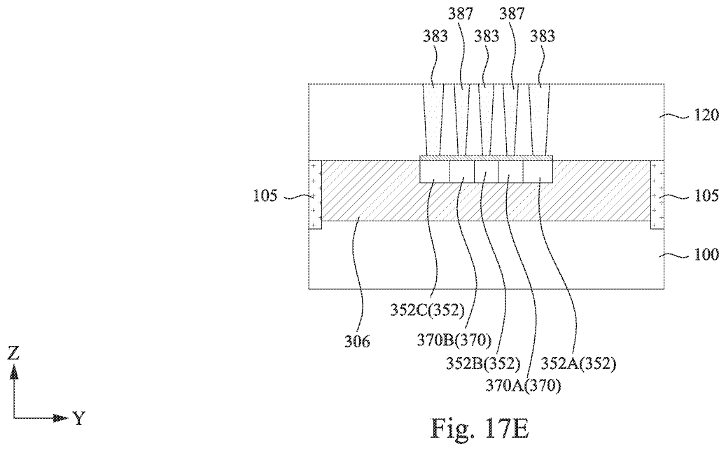

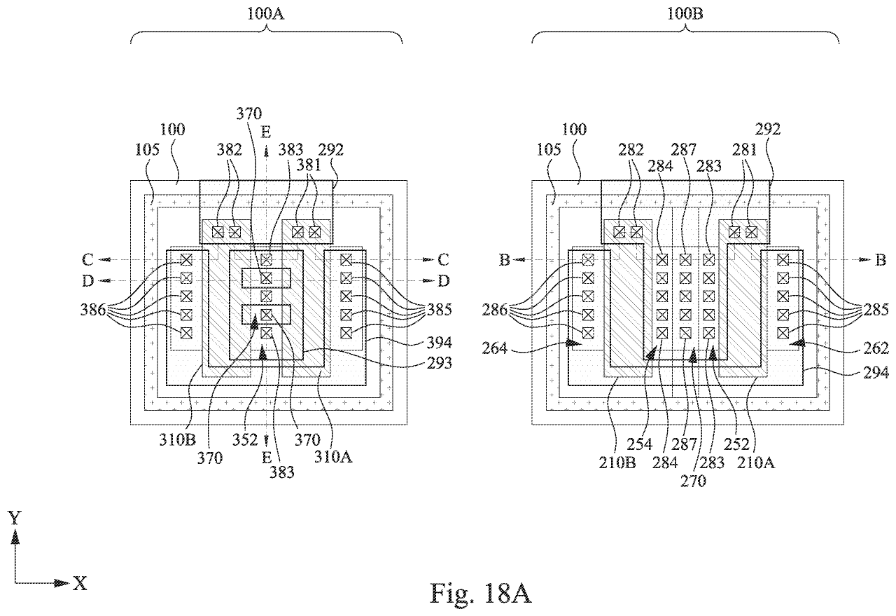

Reference is made to FIGS. 17A to 17E, in which FIG. 17B is a cross-sectional view along line B-B of FIG. 17A, and FIG. 17C is a cross-sectional view along line C-C of FIG. 17A, FIG. 17D is a cross-sectional view along line D-D of FIG. 17A, and FIG. 17E is a cross-sectional view along line E-E of FIG. 17A. An interlayer dielectric (ILD) layer 120 is formed over the substrate 100. In some embodiments, the ILD layer 120 may be formed by, physical vapor deposition (PVD), chemical vapor deposition (CVD), atomic layer deposition (ALD), or another suitable formation process.

Contact plugs 281, 282, 283, 284, 285, 286, 287 and contact plugs 381, 382, 383, 385, 386, 387 are formed in the ILD layer 120. The contacts 281, 282, 283, 284, 285, 286, 287, 381, 382, 383, 385, 386, and 387 may be formed by selectively etching the ILD layer 120 to form openings (e.g. with a patterned photoresist mask in place), and by subsequently depositing a conductive material within the openings. A planarization process may be subsequently performed to remove excess conductive material outside of the openings. In some embodiments, the planarization process may comprise a chemical mechanical polishing (CMP) process.

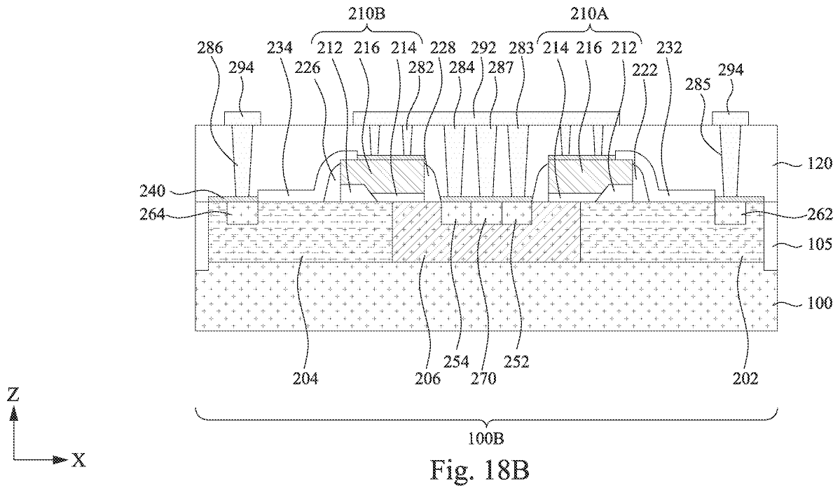

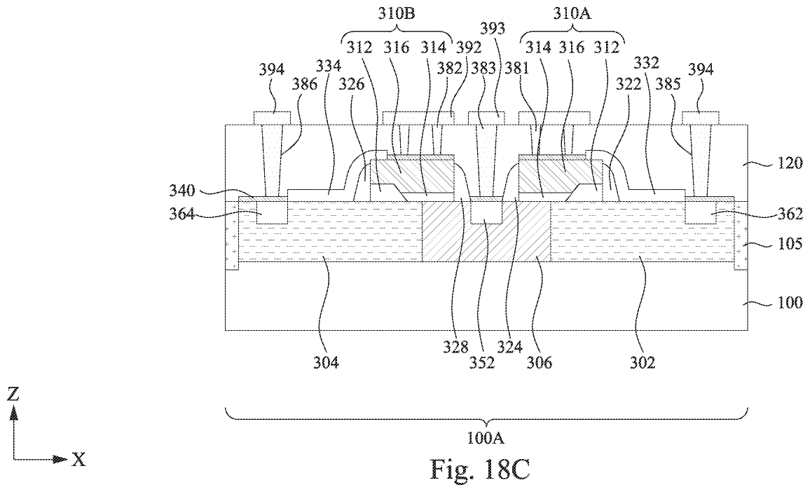

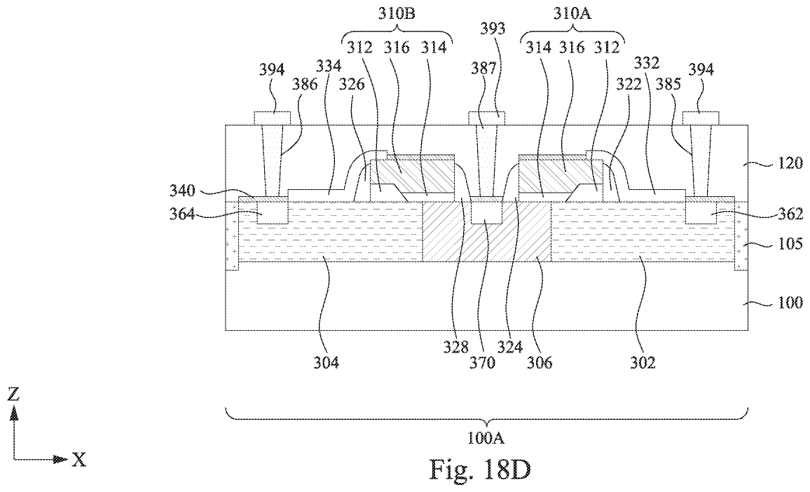

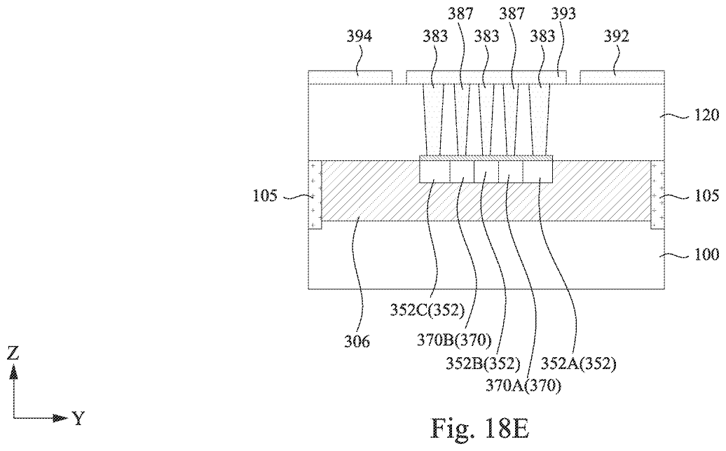

Reference is made to FIGS. 18A to 18E, in which FIG. 18B is a cross-sectional view along line B-B of FIG. 18A, and FIG. 18C is a cross-sectional view along line C-C of FIG. 18A, FIG. 18D is a cross-sectional view along line D-D of FIG. 18A, and FIG. 18E is a cross-sectional view along line E-E of FIG. 18A. Metal lines 292, 294, 392, 393, 394 are formed over the ILD layer 120. In some embodiments, the metal lines 292, 294, 392, 393, 394 may be formed by, for example, depositing a conductive layer over the ILD layer 120, and then patterning the conductive layer according to a pre-determined pattern.

Referring back to FIG. 4. After the metal lines 292, 294, 392, 393, 394 are formed. A driver 50 may be connected to the metal line 392. A supply voltage terminal Vin may be connected to the metal line 394. The metal line 393 and the metal line 294 may be connected to each other through, for example, an interconnection structure or a wire bonding. An inductor 20 is electrically connected to the metal line 393 and the metal line 294. A capacitor 30 and a resistor 40 are electrically connected to the inductor 20. Another side of each of the capacitor 30 and the resistor 40 are connected to the metal line 292. Accordingly, a converter may be formed.

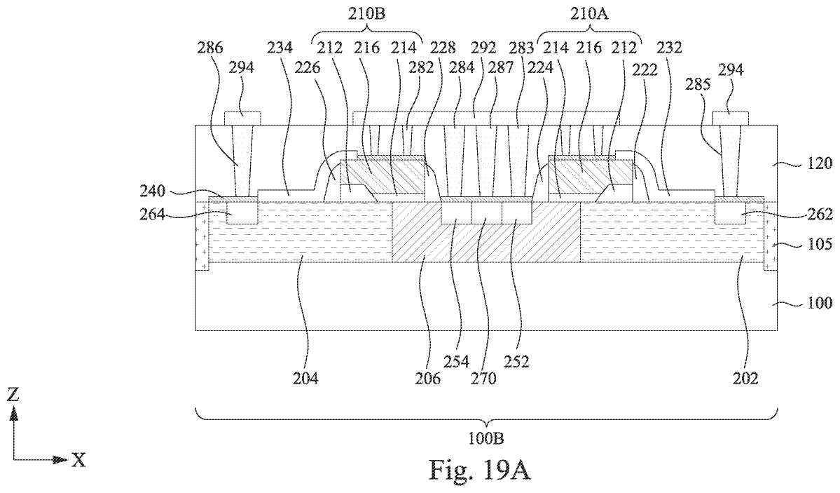

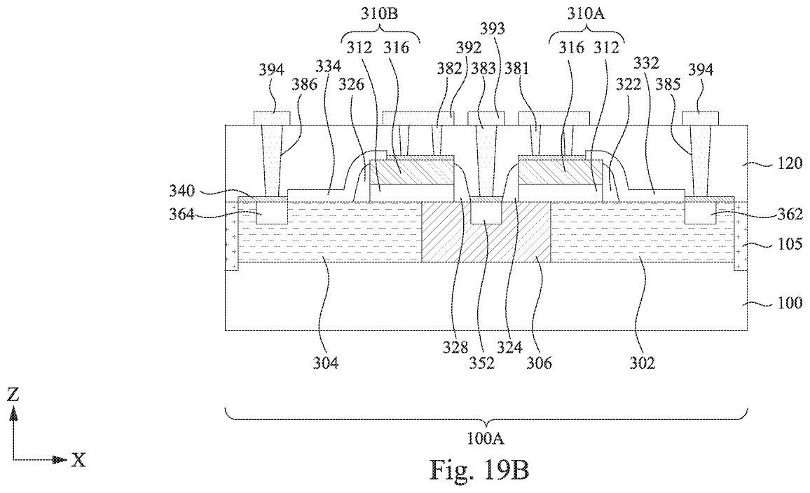

FIGS. 19A and 19B illustrate cross-sectional views of a converter in accordance with some embodiments of the present disclosure. In some embodiments, some elements described in FIGS. 19A and 19B may be similar to the same as those described with respect to FIGS. 1 to 18E, such elements are labeled the same and relevant details will not be repeated for brevity. FIGS. 19A and 19B illustrate the same cross-sectional views of FIGS. 3B and 3C, respectively. The difference between the structure of FIGS. 19A and 19B and the structure of FIGS. 3B and 3C is that, each of the gate structures 310A and 310B may include a single gate dielectric 312. That is, the gate dielectrics 314 of the gate structures 310A and 310B as shown in FIGS. 3A and 3B are omitted. In some embodiments, the gate dielectrics 212 and 214 of the gate structures 210A/210B can be collectively referred to as a first gate dielectric of the gate structures 210A/210B, and the gate dielectric 312 of the gate structures 310A/310B can be referred to as a second gate dielectric of the gate structures 310A/310B. In the embodiments of FIGS. 19A and 19B, the thickness variation of the first gate dielectric of the gate structures 210A/210B is greater than the thickness variation of the second gate dielectric of the gate structures 310A/310B. In some embodiments, to form the gate dielectric 312 as described in FIGS. 19A and 19B, the opening O2 of the patterned mask MA1 of FIG. 6B can be omitted. That is, the patterned mask MA1 of FIG. 6B may cover the gate dielectric layer 311 of FIG. 6B, and thus no portion of the gate dielectric layer 311 of FIG. 6B will be removed prior to forming the gate structures 310A and 310B. In some embodiments, if the drive voltage of the HS transistor Q1 is high, a single gate dielectric 312 with greater thickness may be beneficial for reliability.

Based on the above discussion, it can be seen that the present disclosure offers advantages. It is understood, however, that other embodiments may offer additional advantages, and not all advantages are necessarily disclosed herein, and that no particular advantages is required for all embodiments. Embodiments of the present disclosure provide a converter. By shorting gate/bulk/source together for a low-side transistor of the converter, it may be beneficial for lowering power consumption, and will improve the device performance. Gate structure of the low-side transistor is designed to have a dual gate dielectric configuration, which includes a thicker gate dielectric and a thinner gate dielectric. The thicker gate dielectric may be beneficial for device reliability, and the thinner gate dielectric may be beneficial for lowering threshold voltage. Moreover, pick-up region of the low-side transistor is laterally separated from the gate structure of the low-side transistor by a source region of the low-side transistor, which will effectively increase the channel area, and will further improve the device performance.

In some embodiments of the present disclosure, a converter includes a substrate, a first transistor, a second transistor, a first gate contact plug, a first source contact plug, a first metal line, and an inductor. The first transistor is over the substrate and includes a first gate structure, and a first source region and a first drain region in the substrate and on opposite sides of the first gate structure. The second transistor is over the substrate and includes a second gate structure, and a second source region and a second drain region in the substrate and on opposite sides of the second gate structure. The first gate contact plug is electrically connected to the first gate structure. The first source contact plug is electrically connected to the first source region. The first metal line is in contact with a top surface of the first gate contact plug and a top surface of the first source contact plug. The inductor is electrically connected to the first drain region of the first transistor and the second source region of the second transistor.

In some embodiments, the first transistor further includes a pick-up region in the substrate, the pick-up region and the first source region have opposite conductivity types, and the converter further includes a pick-up contact plug electrically connected to the pick-up region, in which the first metal line is also in contact with a top surface of the pick-up contact plug.

In some embodiments, the first transistor further includes a first pick-up region in the substrate and laterally adjacent to the first source region along a first direction, the first pick-up region and the first source region have opposite conductivity types, the second transistor further includes a second pick-up region in the substrate and laterally adjacent to the second source region along a second direction perpendicular to the first direction, the second pick-up region and the second source region have opposite conductivity types.

In some embodiments, a lateral distance between the first pick-up region and the first gate structure is greater than a lateral distance between the second pick-up region and the second gate structure.

In some embodiments, the converter further includes a second gate contact plug electrically connected to the second gate structure, a second source contact plug electrically connected to the second source region, a second metal line in contact with a top surface of the second gate contact plug, and a third metal line in contact with a top surface of the second source contact plug, in which the second metal line is laterally separated from the third metal line.

In some embodiments, the first gate structure includes a first gate dielectric, a second gate dielectric adjacent to the first gate dielectric, in which the first gate dielectric is thicker than the second gate dielectric, and a gate electrode over the first gate dielectric and the second gate dielectric.

In some embodiments, the first gate dielectric is closer to the first drain region than the second gate dielectric.

In some embodiments, the first gate dielectric forms an inclined interface with the second gate dielectric.

In some embodiments of the present disclosure, a converter includes a substrate, a high-side transistor, a low-side transistor, and an inductor. The high-side transistor is over the substrate and includes a first gate structure, a first source region and a first drain region in the substrate and on opposite sides of the first gate structure, and a first pick-up region in the substrate and laterally adjacent to the first source region along a first direction. The low-side transistor is over the substrate and includes a second gate structure, a second source region and a second drain region in the substrate and on opposite sides of the second gate structure, and a second pick-up region in the substrate and laterally adjacent to the second source region along a second direction perpendicular to the first direction. The inductor electrically connected to the first source region of the high-side transistor and the second drain region of the low-side transistor.

In some embodiments, the converter further includes a first gate contact plug electrically connected to the second gate structure, a first source contact plug electrically connected to the second source region, a first pick-up contact plug electrically connected to the second pick-up region, and a first metal line in contact with a top surface of the first gate contact plug, a top surface of the first source contact plug, and a top surface of the first pick-up contact plug.

In some embodiments, the converter further includes first source contact plugs electrically connected to the first source region, and second source contact plugs electrically connected to the second source region, in which a number of the first source contact plugs is less than a number of the second source contact plugs.

In some embodiments, the converter further includes first pick-up contact plugs electrically connected to the first pick-up region, and second pick-up contact plugs electrically connected to the second pick-up region, in which a number of the first pick-up contact plugs is less than a number of the second pick-up contact plugs.

In some embodiments, the second direction is perpendicular to a lengthwise direction of the first and second gate structures.

In some embodiments, the second gate structure includes a first gate dielectric, a second gate dielectric adjacent to the first gate dielectric, in which the first gate dielectric forms an inclined interface with the second gate dielectric, a gate electrode over the first gate dielectric and the second gate dielectric.

In some embodiments, the first gate structure includes a first gate dielectric, and the second gate structure includes a second gate dielectric, in which the second gate dielectric has a greater thickness variation than the first gate dielectric.

In some embodiments of the present disclosure, a method includes forming a first gate dielectric layer over a substrate; patterning the first gate dielectric layer to expose a portion of the substrate; forming a second gate dielectric layer over the portion of the substrate and in contact with the first gate dielectric layer, in which the second gate dielectric layer is thinner than the first gate dielectric layer; forming a gate electrode layer over the first gate dielectric layer and the second gate dielectric layer; patterning the gate electrode layer, the first gate dielectric layer, and the second gate dielectric layer to form a first gate structure and a second gate structure, in which the first gate structure includes a first remaining portion of the gate electrode layer, a first remaining portion of the first gate dielectric layer, and a first remaining portion of the second gate dielectric layer, and the second gate structure includes a second remaining portion of the gate electrode layer and a second portion of the first gate dielectric layer; forming first source and drain regions in the substrate and on opposite sides of the first gate structure; forming second source and drain regions in the substrate and on opposite sides of the second gate structure; and electrically connecting an inductor to the first drain region and the second source region.

In some embodiments, the method further includes forming a first gate contact plug electrically connected to the first gate structure and a first source contact plug electrically connected to the first source region, and forming a first metal line in contact with a top surface of the first gate contact plug and a top surface of the first source contact plug.

In some embodiments, the method further includes forming a pick-up region in the substrate and laterally adjacent to the first source region, the pick-up region and the first source region having opposite conductivity types, and forming a pick-up contact plug electrically connected to the pick-up region, in which the first metal line is also in contact with a top surface of the pick-up contact plug.

In some embodiments, patterning the first gate dielectric layer to expose the portion of the substrate includes etching the first gate dielectric layer such that the etched first gate dielectric layer has an inclined sidewall.

In some embodiments, the method further includes forming a first pick-up region in the substrate and laterally adjacent to the first source region along a first direction, the first pick-up region and the first source region having opposite conductivity types, and forming a second pick-up region in the substrate and laterally adjacent to the second source region along a second direction perpendicular to the first direction, the second pick-up region and the second source region having opposite conductivity types.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A converter, comprising:
a substrate;
a first transistor over the substrate, comprising:
a first gate structure; and
a first source region and a first drain region in the substrate and on opposite sides of the first gate structure;
a second transistor over the substrate, comprising:
a second gate structure; and
a second source region and a second drain region in the substrate and on opposite sides of the second gate structure;
a first gate contact plug electrically connected to the first gate structure;
a first source contact plug electrically connected to the first source region;
a first metal line in contact with a top surface of the first gate contact plug and a top surface of the first source contact plug; and
an inductor electrically connected to the first drain region of the first transistor and the second source region of the second transistor.

2. The converter of claim 1, wherein the first transistor further comprises a pick-up region in the substrate, the pick-up region and the first source region have opposite conductivity types, and the converter further comprises a pick-up contact plug electrically connected to the pick-up region, wherein the first metal line is also in contact with a top surface of the pick-up contact plug.

3. The converter of claim 1, wherein,
the first transistor further comprises a first pick-up region in the substrate and laterally adjacent to the first source region along a first direction, the first pick-up region and the first source region have opposite conductivity types,
the second transistor further comprises a second pick-up region in the substrate and laterally adjacent to the second source region along a second direction perpendicular to the first direction, the second pick-up region and the second source region have opposite conductivity types.

4. The converter of claim 3, wherein a lateral distance between the first pick-up region and the first gate structure is greater than a lateral distance between the second pick-up region and the second gate structure.

5. The converter of claim 1, further comprising:
a second gate contact plug electrically connected to the second gate structure;
a second source contact plug electrically connected to the second source region;
a second metal line in contact with a top surface of the second gate contact plug; and
a third metal line in contact with a top surface of the second source contact plug, wherein the second metal line is laterally separated from the third metal line.

6. The converter of claim 1, wherein the first gate structure comprises:
a first gate dielectric;
a second gate dielectric adjacent to the first gate dielectric, wherein the first gate dielectric is thicker than the second gate dielectric; and
a gate electrode over the first gate dielectric and the second gate dielectric.

7. The converter of claim 6, wherein the first gate dielectric is closer to the first drain region than the second gate dielectric.

8. The converter of claim 6, wherein the first gate dielectric forms an inclined interface with the second gate dielectric.

9. A converter, comprising:
a substrate;
a high-side transistor over the substrate, comprising:
a first gate structure;
a first source region and a first drain region in the substrate and on opposite sides of the first gate structure; and
a first pick-up region in the substrate and laterally adjacent to the first source region along a first direction;
a low-side transistor over the substrate, comprising:
a second gate structure;
a second source region and a second drain region in the substrate and on opposite sides of the second gate structure; and
a second pick-up region in the substrate and laterally adjacent to the second source region along a second direction perpendicular to the first direction; and
an inductor electrically connected to the first source region of the high-side transistor and the second drain region of the low-side transistor.

10. The converter of claim 9, further comprising:
a first gate contact plug electrically connected to the second gate structure;
a first source contact plug electrically connected to the second source region;
a first pick-up contact plug electrically connected to the second pick-up region; and
a first metal line in contact with a top surface of the first gate contact plug, a top surface of the first source contact plug, and a top surface of the first pick-up contact plug.

11. The converter of claim 9, further comprising:
first source contact plugs electrically connected to the first source region; and
second source contact plugs electrically connected to the second source region, wherein a number of the first source contact plugs is less than a number of the second source contact plugs.

12. The converter of claim 9, further comprising:
first pick-up contact plugs electrically connected to the first pick-up region; and
second pick-up contact plugs electrically connected to the second pick-up region, wherein a number of the first pick-up contact plugs is less than a number of the second pick-up contact plugs.

13. The converter of claim 9, wherein the second direction is perpendicular to a lengthwise direction of the first and second gate structures.

14. The converter of claim 9, wherein the second gate structure comprises:
a first gate dielectric;
a second gate dielectric adjacent to the first gate dielectric, wherein the first gate dielectric forms an inclined interface with the second gate dielectric; and
a gate electrode over the first gate dielectric and the second gate dielectric.

15. The converter of claim 9, wherein the first gate structure comprises a first gate dielectric, and the second gate structure comprises a second gate dielectric, wherein the second gate dielectric has a greater thickness variation than the first gate dielectric.

16. A method, comprising:
forming a first gate dielectric layer over a substrate;
patterning the first gate dielectric layer to expose a portion of the substrate;
forming a second gate dielectric layer over the portion of the substrate and in contact with the first gate dielectric layer, wherein the second gate dielectric layer is thinner than the first gate dielectric layer;
forming a gate electrode layer over the first gate dielectric layer and the second gate dielectric layer;
patterning the gate electrode layer, the first gate dielectric layer, and the second gate dielectric layer to form a first gate structure and a second gate structure, wherein the first gate structure comprises a first remaining portion of the gate electrode layer, a first remaining portion of the first gate dielectric layer, and a first remaining portion of the second gate dielectric layer, and the second gate structure comprises a second remaining portion of the gate electrode layer and a second portion of the first gate dielectric layer;
forming first source and drain regions in the substrate and on opposite sides of the first gate structure;
forming second source and drain regions in the substrate and on opposite sides of the second gate structure; and
electrically connecting an inductor to the first drain region and the second source region.

17. The method of claim 16, further comprising:
forming a first gate contact plug electrically connected to the first gate structure and a first source contact plug electrically connected to the first source region; and
forming a first metal line in contact with a top surface of the first gate contact plug and a top surface of the first source contact plug.

18. The method of claim 17, further comprising:
forming a pick-up region in the substrate and laterally adjacent to the first source region, the pick-up region and the first source region having opposite conductivity types; and
forming a pick-up contact plug electrically connected to the pick-up region, wherein the first metal line is also in contact with a top surface of the pick-up contact plug.

19. The method of claim 16, wherein patterning the first gate dielectric layer to expose the portion of the substrate comprises etching the first gate dielectric layer such that the etched first gate dielectric layer has an inclined sidewall.

20. The method of claim 16, further comprising:
forming a first pick-up region in the substrate and laterally adjacent to the first source region along a first direction, the first pick-up region and the first source region having opposite conductivity types; and
forming a second pick-up region in the substrate and laterally adjacent to the second source region along a second direction perpendicular to the first direction, the second pick-up region and the second source region having opposite conductivity types.
